(19) United States
(12) Patent Application Publication
(10) Pub. No.: US 2019/0131470 A1
(43) Pub. Date: May 2, 2019

(54) ARTIFICIAL PHOTOSYNTHESIS MODULE AND ARTIFICIAL PHOTOSYNTHESIS DEVICE

(71) Applicants: FUJIFILM Corporation, Tokyo (JP); Japan Technological Research Association of Artificial Photosynthetic Chemical Process, Tokyo (JP)

(72) Inventors: Hiroshi NAGATE, Ashigara-kami-gun (JP); Hiroyuki KOBAYASHI, Kashiwa-shi (JP)

(73) Assignees: FUJIFILM Corporation, Tokyo (JP); Japan Technological Research Association of Artificial Photosynthetic Chemical Process, Tokyo (JP)

(21) Appl. No.: 16/228,398

(22) Filed: Dec. 20, 2018

Related U.S. Application Data
(63) Continuation of application No. PCT/JP2017/022461, filed on Jun. 19, 2017.

(30) Foreign Application Priority Data
Jun. 23, 2016 (JP) 2016-124514

(51) Int. Cl. H01L 31/0224; C25B 1/06; C25B 1/00; C25B 1/10

(52) U.S. Cl. CPC H01L 31/022425; C25B 1/06; H01L 2031/0344; C25B 1/10; C25B 1/003

(57) ABSTRACT

Provided are an artificial photosynthesis module and an artificial photosynthesis device that have excellent energy conversion efficiency. The artificial photosynthesis module includes a first electrode that decomposes a raw material fluid with light to obtain a first fluid; a second electrode that decomposes the raw material fluid with the light to obtain a second fluid; and a diaphragm disposed between the first electrode and the second electrode. The diaphragm is formed of a membrane having through-holes, is immersed in pure water having a temperature of 25° C. for one minute, and has a light transmittance of 60% or more in a wavelength range of 380 nm to 780 nm in a state where the diaphragm is immersed in the pure water. The average hole diameter of the through-holes of the diaphragm is more than 0.1 μm and less than 50 μm. An artificial photosynthesis device has the above-described artificial photosynthesis module.

### CROSS-REFERENCE TO RELATED APPLICATIONS

This application is a Continuation of PCT International Application No. PCT/JP2017/22461 filed on Jun. 19, 2017, which claims priority under 35 U.S.C. § 119(a) to Japanese Patent Application No. 2016-124514 filed on Jun. 23, 2016. The above application is hereby expressly incorporated by reference, in its entirety, into the present application.

### BACKGROUND OF THE INVENTION

### 1. Field of the Invention

The invention relates to an artificial photosynthesis module and an artificial photosynthesis device that that have a first electrode that decomposes a raw material fluid with light to obtain a first fluid, and a second electrode that decomposes a raw material fluid with light to obtain a second fluid, and particularly, to an artificial photosynthesis module and an artificial photosynthesis device in which a transparent diaphragm, which is formed of a porous membrane and is immersed in water, is disposed between the first electrode and the second electrode.

### 2. Description of the Related Art

Nowadays, water is decomposed using a photocatalyst and utilizing solar light energy, which is renewable energy, to obtain gases, such as hydrogen gas and oxygen gas.

For example, JP2006-089336A discloses a hydrogen and oxygen producing device including a hydrogen evolution cell including a visible light responsive photocatalyst, a redox medium, and a counter electrode, an oxygen evolution cell having a semiconductor electrode, and means for electrically connecting the counter electrode and the semiconductor electrode. In JP2006-089336A, the hydrogen evolution cell and the oxygen evolution cell communicate with each other by means of an ion-exchange membrane. Nafion (registered trademark) is exemplified as the ion-exchange membrane.

### SUMMARY OF THE INVENTION

In the hydrogen and oxygen producing device of JP2006-089336A, the hydrogen evolution cell and the oxygen evolution cell are allowed to communicate with each other without providing the electrode with through-holes, and the ion-exchange membrane is interposed between the cells. In this case, since the movement distance of ions, which are produced in the oxygen evolution cell, in the electrolytic solution becomes large, energy conversion efficiency decreases.

Additionally, in a case where Nafion (registered trademark) is used for the ion-exchange membrane as in JP2006-089336A, ion movement efficiency decreases and overpotential increases. Additionally, since Nafion (registered trademark) conduct protons and ions, and is a polymer electrolyte, and is not porous, the electrolytic solution cannot be moved. For this reason, in Nafion (registered trademark), protons and ions cannot be moved without resistance together with the electrolytic solution, and movement resistance is generated. Accordingly, the energy conversion efficiency decreases.

Additionally, in a case where the electrode is provided with the through-holes in order to suppress the above-described movement resistance and in a case where the through-holes are large, produced oxygen and hydrogen are mixed with each other. Thus, it is difficult to recover the produced oxygen and hydrogen in high purity. From this fact, the evolution efficiency of oxygen and hydrogen also decreases.

An object of the invention is to solve the problems based on the aforementioned related art and provide an artificial photosynthesis module and an artificial photosynthesis device having excellent energy conversion efficiency.

In order to achieve the above-described object, the invention provides an artificial photosynthesis module comprising a first electrode that decomposes a raw material fluid with light to obtain a first fluid; a second electrode that decomposes the raw material fluid with the light to obtain a second fluid; and a diaphragm disposed between the first electrode and the second electrode. The diaphragm is formed of a membrane having through-holes, is immersed in pure water having a temperature of 25° C. for one minute, and has a light transmittance of 60% or more in a wavelength range of 380 nm to 780 nm in a state where the diaphragm is immersed in the pure water. An average hole diameter of the through-holes of the diaphragm is more than 0.1 μm and less than 50 μm.

It is preferable that the diaphragm is formed of a porous membrane having a hydrophilic surface.

It is preferable that the first electrode has a first substrate, a first conductive layer provided on the first substrate, a first photocatalyst layer provided on the first conductive layer, and a first co-catalyst carried and supported on at least a portion of the first photocatalyst layer, the second electrode has a second substrate, a second conductive layer provided on the second substrate, a second photocatalyst layer provided on the second conductive layer, and a second co-catalyst carried and supported on at least a portion of the second photocatalyst layer, and the first electrode, the diaphragm, and the second electrode are disposed in series in a traveling direction of the light.

It is preferable that the light is incident from the first electrode side, and the first substrate of the first electrode is transparent.

It is preferable that the first electrode and the second electrode have a plurality of through-holes, and the diaphragm is disposed and sandwiched between the first electrode and the second electrode.

It is preferable that the first fluid is a gas or a liquid, and the second fluid is a gas or a liquid.

It is preferable that the raw material fluid is water, the first fluid is oxygen, and the second fluid is hydrogen.

The invention provides an artificial photosynthesis device comprising an artificial photosynthesis module that decomposes a raw material fluid to obtain a fluid; a tank that stores the raw material fluid; a supply pipe that is connected to the tank and the artificial photosynthesis module and supplies the raw material fluid to the artificial photosynthesis module; a discharge pipe that is connected to the tank and the artificial photosynthesis module and recovers the raw material fluid from the artificial photosynthesis module; a pump that circulates the raw material fluid between the tank and the artificial photosynthesis module via the supply pipe and the discharge pipe; and a gas recovery unit that recovers the fluids obtained by the artificial photosynthesis module. A plurality of the artificial photosynthesis modules are disposed, each artificial photosynthesis module including a first electrode having a first substrate that decomposes the raw material fluid with light to obtain a first fluid, a first conductive layer provided on the first substrate, a first photocatalyst layer provided on the first conductive layer, and a first co-catalyst carried and supported on at least a portion of the first photocatalyst layer; a second electrode having a second substrate that decomposes the raw material fluid with the light to obtain a second fluid, a second conductive layer provided on the second substrate, a second photocatalyst layer provided on the second conductive layer, and a second co-catalyst carried and supported on at least a portion of the second photocatalyst layer; and a diaphragm provided between the first electrode and the second electrode. The first electrode and the second electrode are electrically connected to each other via a conducting wire. The diaphragm is formed of a membrane having through-holes, is immersed in pure water having a temperature of 25° C. for one minute, and has a light transmittance of 60% or more in a wavelength range of 380 nm to 780 nm in a state where the membrane is immersed in the pure water. An average hole diameter of the through-holes of the diaphragm is more than 0.1 μm and less than 50 μm.

It is preferable that the artificial photosynthesis module has a first compartment provided with the first electrode and a second compartment provided with the second electrode, which are partitioned by the diaphragm, the supply pipe supplies the raw material fluid to the first compartment and the second compartment, the discharge pipe recovers the raw material fluids of the first compartment and the second compartment, the raw material fluid of the first compartment and the raw material fluid of the second compartment in the artificial photosynthesis module are mixed with each other and stored in the tank that stores the raw material fluid, and the raw material fluids that are mixed with each other and stored in the tank are supplied to the first compartment and the second compartment via the supply pipe by the pump.

It is preferable that the first fluid is a gas or a liquid, and the second fluid is a gas or a liquid.

It is preferable that the raw material fluid is water, the first fluid is oxygen, and the second fluid is hydrogen.

According to the invention, the energy conversion efficiency can be made excellent.

### BRIEF DESCRIPTION OF THE DRAWINGS

FIG. 1 is a schematic cross-sectional view illustrating a first example of an artificial photosynthesis module of an embodiment of the invention.

FIG. 2 is a schematic plan view illustrating the first example of the artificial photosynthesis module of the embodiment of the invention.

FIG. 3 is a schematic cross-sectional view illustrating an example of an oxygen evolution electrode.

FIG. 4 is a schematic cross-sectional view illustrating an example of a hydrogen evolution electrode.

FIG. 5 is a schematic perspective view illustrating a diaphragm.

FIG. 6 is a graph that illustrates an example of transmittance.

FIG. 7 is a schematic cross-sectional view illustrating a second example of the artificial photosynthesis module of the embodiment of the invention.

FIG. 8 is a schematic cross-sectional view illustrating a third example of the artificial photosynthesis module of the embodiment of the invention.

FIG. 9 is a schematic cross-sectional view illustrating a fourth example of the artificial photosynthesis module of the embodiment of the invention.

FIG. 10 is a schematic cross-sectional view illustrating a fifth example of the artificial photosynthesis module of the embodiment of the invention.

FIG. 11 is a schematic plan view illustrating an electrode configuration of the fifth example of the artificial photosynthesis module of the embodiment of the invention.

FIG. 12 is a schematic view illustrating a first example of an artificial photosynthesis device of the embodiment of the invention.

FIG. 13 is a schematic view illustrating a second example of the artificial photosynthesis device of the embodiment of the invention.

FIG. 14 is a schematic view illustrating a third example of the artificial photosynthesis device of the embodiment of the invention.

FIG. 15 is a schematic view illustrating a fourth example of the artificial photosynthesis device of the embodiment of the invention.

### DESCRIPTION OF THE PREFERRED EMBODIMENTS

Hereinafter, an artificial photosynthesis module and an artificial photosynthesis device of the invention will be described in detail with reference to preferred embodiments illustrated in the attached drawings.

In addition, in the following, “to” showing a numerical range includes numerical values described on both sides thereof. For example, ε being a numerical value α1 to a numerical value β1 means that the range of ε is a range including the numerical value α1 and the numerical value β1, and in a case where these are expressed by mathematical symbols, α1≤ε≤β1 is satisfied.

Angles including “parallel” and “perpendicular” include error ranges generally allowed in the technical field unless otherwise specified.

The artificial photosynthesis module of the invention decomposes a raw material fluid serving as a decomposition target by utilizing light energy to obtain substance different from the raw material fluid, decomposes the raw material fluid with light to obtain a first fluid and a second fluid.

The artificial photosynthesis module has a first electrode that decomposes the raw material fluid with light to obtain the first fluid, and a second electrode that decomposes the raw material fluid with light to obtain the second fluid. In addition, as long as the first fluid and second fluid are fluids, respectively, the first fluid and the second fluid are not particularly limited and are gases or liquids.

In addition, the above-described different substances are substances that can be obtained by oxidizing or reducing the raw material fluid.

Hereinafter, an artificial photosynthesis module and an artificial photosynthesis device will be described.

The artificial photosynthesis module will be described taking a case where the raw material fluid is water, the first fluid is oxygen, and the second fluid is hydrogen as an example.

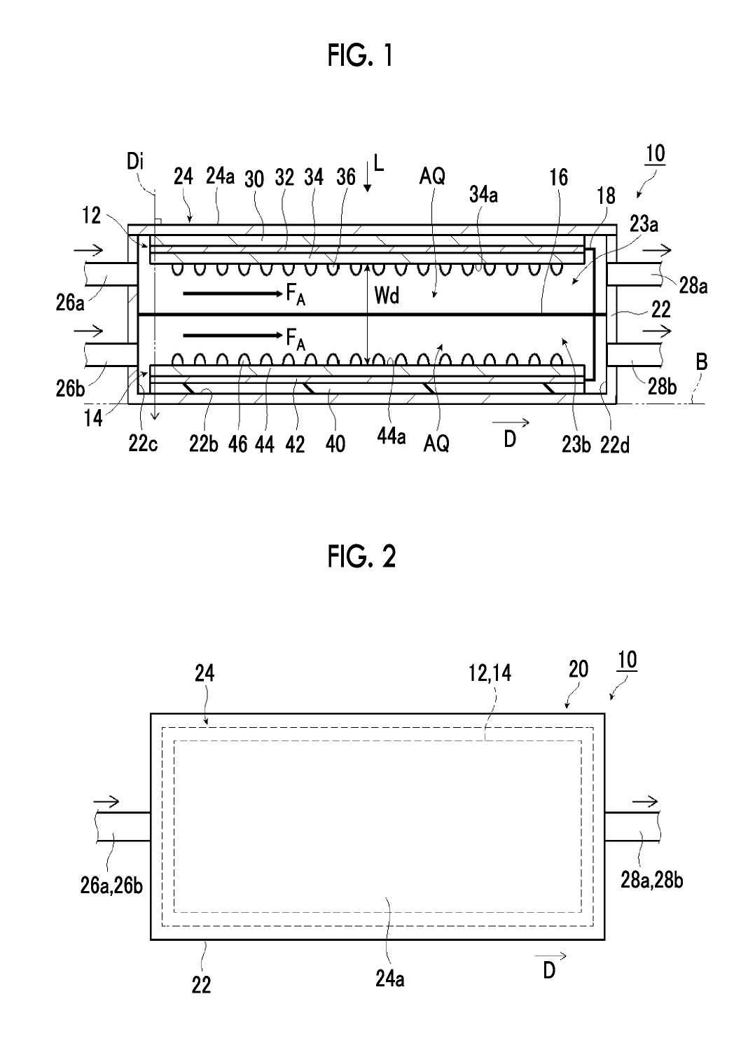

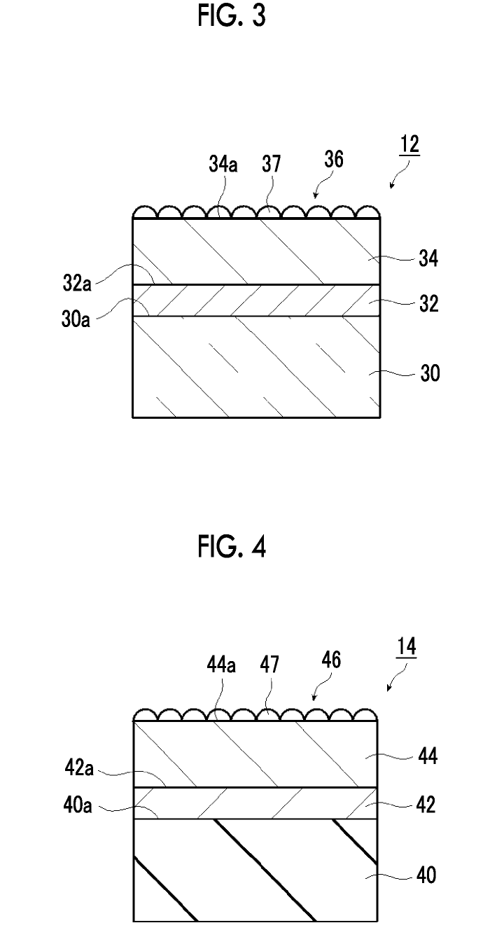

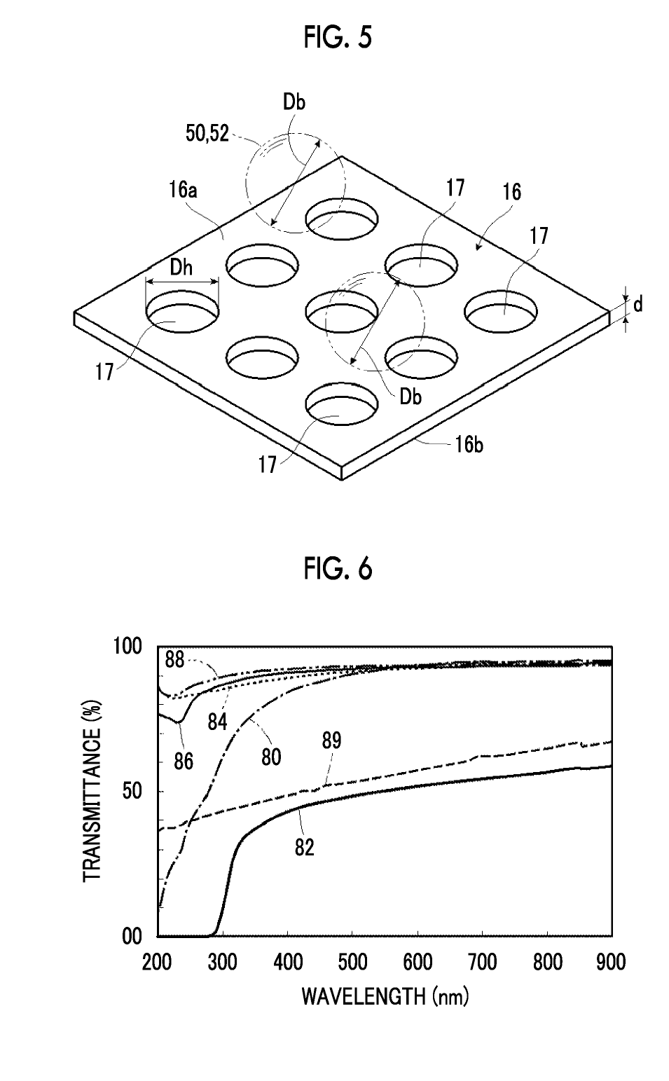

FIG. 1 is a schematic cross-sectional view illustrating a first example of an artificial photosynthesis module of an embodiment of the invention, and FIG. 2 is a schematic plan view illustrating the first example of the artificial photosynthesis module of the embodiment of the invention. FIG. 3 is a schematic cross-sectional view illustrating an example of an oxygen evolution electrode, and FIG. 4 is a schematic cross-sectional view illustrating an example of a hydrogen evolution electrode. FIG. 5 is a schematic perspective view illustrating a diaphragm.

The artificial photosynthesis module 10 illustrated in FIG. 1 is, for example, one capable of decomposing water AQ, which is a raw material fluid, with light L to produce oxygen that is a first fluid, and hydrogen that is a second fluid. The artificial photosynthesis module 10 has, for example, an oxygen evolution electrode 12, a hydrogen evolution electrode 14, and a diaphragm 16 provided between the oxygen evolution electrode 12 and the hydrogen evolution electrode 14. The artificial photosynthesis module 10 is a two-electrode water decomposition module having the oxygen evolution electrode 12 and the hydrogen evolution electrode 14. For example, the oxygen evolution electrode 12 and the hydrogen evolution electrode 14 are used for decomposition of the water AQ in a state where the electrodes are immersed in the water AQ.

The artificial photosynthesis module 10 has a container 20 that houses the oxygen evolution electrode 12, the hydrogen evolution electrode 14, and the diaphragm 16. The container 20 is disposed, for example, on a horizontal plane B.

The oxygen evolution electrode 12 decomposes the water AQ to produce oxygen gas in a state where the oxygen evolution electrode 12 is immersed in the water AQ, and has, for example, a flat plate shape as a whole as illustrated in FIG. 2.

The hydrogen evolution electrode 14 decomposes the water AQ to produce hydrogen gas in a state where the hydrogen evolution electrode 14 is immersed in the water AQ, and has, for example, a flat plate shape as a whole as illustrated in FIG. 2.

As illustrated in FIG. 1, the container 20 has a housing 22 of which one face is open, and a transparent member 24 that covers the open portion of the housing 22. The interior of a container 20 is partitioned into a first compartment 23a on the transparent member 24 side, and a second compartment 23b on a bottom face 22b side by the diaphragm 16. The light L is, for example, solar light and is incident from the transparent member 24 side. It is preferable that the transparent member 24 also satisfy the specifications of the “transparent” to be described below.

The oxygen evolution electrode 12 and the hydrogen evolution electrode 14 are electrically connected to each other by, for example, a conducting wire 18. In addition, the oxygen evolution electrode 12 and the hydrogen evolution electrode 14 are disposed in order of the oxygen evolution electrode 12 and the hydrogen evolution electrode 14 with the diaphragm 16 interposed therebetween within the container 20 in series in a traveling direction Di of the light L. In FIG. 1, the oxygen evolution electrode 12 and the hydrogen evolution electrode 14 are overlappingly disposed parallel to each other with a gap therebetween.

It is preferable that a gap Wd between the oxygen evolution electrode 12 and the hydrogen evolution electrode 14 is 1 mm to 20 mm, and the smaller the gap, the better the energy conversion efficiency. In addition, the gap Wd between the oxygen evolution electrode 12 and the hydrogen evolution electrode 14 is a distance between a surface 34a of a first photocatalyst layer 34 of the oxygen evolution electrode 12 and a surface 44a of a second photocatalyst layer 44 of the hydrogen evolution electrode 14.

The oxygen evolution electrode 12 is disposed in the first compartment 23a, and oxygen gas is produced within the first compartment 23a. The hydrogen evolution electrode 14 is disposed in the second compartment 23b such that a second substrate 40 is in contact with on the bottom face 22b, and hydrogen gas is produced within the second compartment 23b.

In addition, the light L is incident from the transparent member 24 side with respect to the container 20, that is, the light L is incident from the oxygen evolution electrode 12 side. The above-described traveling direction Di of the light L is a direction perpendicular to a surface 24a of the transparent member 24.

In the first compartment 23a, a first wall face 22c is provided with a supply pipe 26a, and a second wall face 22d that faces the first wall face 22c is provided with a discharge pipe 28a. In the second compartment 23b, the first wall face 22c is provided with a supply pipe 26b, and the second wall face 22d that faces the first wall face 22c is provided with a discharge pipe 28b. The water AQ is supplied into the container 20 from the supply pipe 26a and the supply pipe 26b, the interior of the container 20 is filled with the water AQ, the water AQ flows in a direction D, the water AQ containing oxygen is discharged from the discharge pipe 28a, and the oxygen is recovered. From the discharge pipe 28b, the water AQ containing hydrogen is discharged and the hydrogen is recovered. In this case, a flow direction F_{A} of the water AQ is the direction D.

The direction D is a direction from the first wall face 22c toward the second wall face 22d. In addition, the housing 22 is formed of, for example, an electrical insulating material that does not cause short circuiting or the like in a case where the hydrogen evolution electrode 14 and the oxygen evolution electrode 12 are used. The housing 22 is formed of, for example, acrylic resin. It is preferable that the container 20 satisfies the specifications of the “transparent” in a first substrate 30 to be described below.

Distilled water, cooling water to be used in a cooling tower, and the like are included in the water AQ. Additionally, an electrolytic aqueous solution is also included in the water AQ. Here, the electrolytic aqueous solution is a liquid having H₂O as a main component, may be an aqueous solution having water as a solvent and containing a solute, and is, for example, an electrolytic solution containing strong alkali (KOH (potassium hydroxide)) and H₂SO₄, a sodium sulfate electrolytic solution, a potassium phosphate buffer solution, or the like. It is preferable that the electrolytic aqueous solution is H₃BO₃ adjusted to pH (hydrogen ion index) 9.5.

In addition, the artificial photosynthesis module 10 may be provided with a supply unit (not illustrated) for supplying the water AQ, and a recovery unit (not illustrated) that recovers the water AQ discharged from the artificial photosynthesis module 10.

Well-known water supply devices, such as a pump, are available for the supply unit, and well-known water recovery devices, such as a tank, are available for the recovery unit.

The supply unit is connected to the artificial photosynthesis module 10 via the supply pipes 26a and 26b, and the recovery unit is connected to the artificial photosynthesis module 10 via the discharge pipes 28a and 28b, so that the water AQ recovered in the recovery unit can be circulated to the supply unit and the water AQ can be utilized again.

Additionally, the water AQ is made to flow parallel to a surface 16a (refer to FIG. 5) and a back face 16b (refer to FIG. 5) of the diaphragm 16, and the flow of the water AQ is made to be a laminar flow on an electrode surface. In this case, a honeycomb straightening plate may be further provided. The flow of the water AQ does not include turbulence, and turbulence is also not included in a flow in the flow direction F_{A} of the water AQ.

Hereinafter, respective units of the artificial photosynthesis module 10 will be described.

As illustrated in FIGS. 1 and 3, the oxygen evolution electrode 12 has the first substrate 30, a first conductive layer 32 provided on the first substrate 30, that is, a surface 30a, a first photocatalyst layer 34 provided on the first conductive layer 32, that is, a surface 32a, and a first co-catalyst 36 that is carried and supported on at least a portion of the first photocatalyst layer 34. The oxygen evolution electrode 12 is a first electrode.

The first co-catalyst 36 is constituted of, for example, a plurality of co-catalyst particles 37. Accordingly, a decrease in the quantity of the light L incident on the surface 34a of the first photocatalyst layer 34 is suppressed. In the oxygen evolution electrode 12, it is required that the first co-catalyst 36 is in contact with the first photocatalyst layer 34 or is in contact with the water AQ with a layer allowing holes to move therethrough interposed therebetween.

An absorption end of the first photocatalyst layer 34 is, for example, about 400 nm to 800 nm.

Here, the absorption end is a portion or its end where an absorption factor decreases abruptly in a case where the wavelength becomes longer than this in a continuous absorption spectrum, and the unit of the absorption end is nm. It is preferable that the total thickness of the oxygen evolution electrode 12 is about 2 mm.

The oxygen evolution electrode 12 allows the light L to be transmitted therethrough in order to make the light L incident on the hydrogen evolution electrode 14. In order to irradiate the hydrogen evolution electrode 14 with the light L, the light L does not need to be transmitted through the oxygen evolution electrode 12, and the first substrate 30 is transparent. In the hydrogen evolution electrode 14, the second substrate 40 (refer to FIG. 4) to be described below does not need to be transparent.

The term “transparent” in the first substrate 30 means that the light transmittance of the first substrate 30 is at least 60% in a region having a wavelength of 380 nm to 780 nm. The above-described light transmittance is measured by a spectrophotometer. As the spectrophotometer, for example, V-770 (product name), which is an ultraviolet-visible spectrophotometer manufactured by JASCO Corporation, is used.

In addition, in a case where the light transmittance is T %, the transmittance is expressed by T=(Σλ(Measurement substance+Substrate)/Σλ(Substrate))×100%. The above-described measurement substance is a glass substrate, and a substrate reference is air. The range of integration is up to a light-receiving wavelength of a photocatalyst layer, in light having a wavelength of 380 nm to 780 nm. In addition, Japanese Industrial Standard (JIS) R 3106-1998 can be referred to for the measurement of the light transmittance.

As illustrated in FIGS. 1 and 4, the hydrogen evolution electrodes 14 have the second substrate 40, a second conductive layer 42 provided on the second substrate 40, that is, a surface 40a, a second photocatalyst layer 44 provided on the second conductive layer 42, that is, a surface 42a, and a second co-catalyst 46 that is carried and supported on at least a portion of the second photocatalyst layer 44. The hydrogen evolution electrode 14 is a second electrode. The absorption end of the second photocatalyst layer 44 of the hydrogen evolution electrode 14 is, for example, about 600 nm to 1300 nm.

The second co-catalyst 46 is provided on the surface 44a of the second photocatalyst layer 44. The second co-catalyst 46 is constituted of, for example, a plurality of co-catalyst particles 47. Accordingly, a decrease in the quantity of the light L incident on the surface 44a of the second photocatalyst layer 44 is suppressed. In the hydrogen evolution electrode 14, the carriers created in a case where the light L is absorbed are generated, and the water AQ is decomposed to produce hydrogen gas.

In the hydrogen evolution electrode 14, as will be described below, it is also preferable to laminate a material having n-type conductivity on the surface 44a of the second photocatalyst layer 44 to form a pn junction. Individual components of the hydrogen evolution electrode 14 will be described below in detail.

As illustrated in FIG. 1, in the artificial photosynthesis module 10, the light L is incident from the oxygen evolution electrode 12 side, and the first photocatalyst layer 34 of the oxygen evolution electrode 12 is provided on a side opposite to an incidence side of the light L. Since the light L is incident from a back face through the first substrate 30 by providing the first photocatalyst layer 34 on the side opposite to the incidence side of the light L, a damping effect of the first photocatalyst layer 34 can be suppressed. The second photocatalyst layer 44 of the hydrogen evolution electrode 14 is provided on the incidence side of the light L.

The diaphragm 16 is constituted of a membrane having through-holes 17 (refer to FIG. 5), is immersed in pure water having a temperature of 25° C. for one minute, and the light transmittance of a wavelength range having a wavelength of 380 nm to 780 nm is 60% or more in a state where the diaphragm 16 is immersed in the pure water. That is, the diaphragm 16 has a light transmittance of at least 60% in the wavelength range having a wavelength of 380 nm to 780 nm. In the diaphragm 16, the light transmittance being 60% or more in the wavelength range having a wavelength of 380 nm to 780 nm as described above is referred to as “transparent”.

In addition, the state where the diaphragm 16 is immersed in the pure water is a state where the entire diaphragm 16 is in the pure water, and the pure water is present on the surface 16a and the back face 16b of the diaphragm 16.

A transmittance measuring device (SH7000 made by NIPPON DENSHOKU, INC.) is used for measurement of the light transmittance of the diaphragm 16. The light transmittance of the diaphragm 16 is measured in a state where the diaphragm 16 is immersed in the pure water after being immersed in the pure water for one minute. The light transmittance is calculated as an amount of light transmitted, which is obtained by integrating all the light transmitted in the wavelength range having a wavelength of 380 nm to 780 nm with an integrating sphere.

As illustrated in FIG. 5, the diaphragm 16 has the plurality of through-holes 17. The respective through-holes 17 are, for example, those that penetrate from the surface 16a to the back face 16b. The through-holes 17 are not particularly limited to those penetrating perpendicularly to the surface 16a as long as the through-holes penetrate from the surface 16a to the back face 16b. In a case where the diaphragm 16 has a two-dimensional mesh structure, openings of a mesh are the through-holes 17. In a case where a diaphragm 16 has a three-dimensional network structure, meshes are the through-holes 17. In a case where the diaphragm 16 is formed of fibers, holes formed by gaps between the fibers are also included in the through-holes 17.

As described above, oxygen gas is produced in the oxygen evolution electrode 12, and hydrogen gas is produced in the hydrogen evolution electrode 14. Both of the oxygen gas produced and the hydrogen gas produced are dissolved within the water AQ. However, in a case where the oxygen gas produced and the hydrogen gas produced are large and cannot be completely dissolved in the water AQ, the oxygen gas and the hydrogen gas may be present in a gaseous state within the water AQ. The oxygen gas, which is not dissolved within the water AQ and is aggregated within the water AQ, is referred to as oxygen gas bubbles. The hydrogen gas, which is not dissolved within the water AQ and is aggregated within the water AQ, is referred to as hydrogen gas bubbles.

The diameters of both of the oxygen gas bubbles and the hydrogen gas bubbles are about 10 μm or more and 1 mm or less. The oxygen gas bubbles and the hydrogen gas bubbles are collectively and simply referred to as bubbles. The diameters of the bubbles are diameters in a case where the bubbles are spheres, and are equivalent diameters equivalent to the diameter of the spheres in a case where the bubbles are not spheres.

Since both of the oxygen gas bubbles and the hydrogen gas bubbles stagnate on the surface of the first photocatalyst layer 34 of the oxygen evolution electrode 12 and the surface of the second photocatalyst layer 44 of the hydrogen evolution electrode 14 until the bubbles have a certain size, bubbles with a small diameter, that is, bubbles with a small size, are not present within the water AQ.

Additionally, bubbles with a large diameter, that is, bubbles with a large size, are separated from the surface of the first photocatalyst layer 34 of the oxygen evolution electrode 12 and the surface of the second photocatalyst layer 44 of the hydrogen evolution electrode 14. However, In a case where the diaphragm 16 has hydrophilicity, the bubbles do not adhere to the diaphragm 16 and are carried from the interior of the container 20 to the outside due to the flow of the water AQ.

The diameter of the oxygen gas bubbles and the diameter of the hydrogen gas bubbles can be measured as follows.

The interior of the container 20, including the surface of the first photocatalyst layer 34 of the oxygen evolution electrode 12 and the surface of the second photocatalyst layer 44 of the hydrogen evolution electrode 14, is imaged using a digital microscope, and a captured image of the interior of container 20 that is captured in an enlarged manner is obtained. The bubbles are checked within the captured image. For example, VHX-5000 made by KEYENCE CORP. can be used for the digital microscope, and image analysis software (Made by KEYENCE CORP.) for VHX-5000 users can be used for the checking of the bubbles.

By setting the number of bubbles for determining average bubble diameters in advance, thereby determining the bubble diameter of the oxygen gas bubbles and the bubble diameter of the hydrogen gas bubbles, the average bubble diameters can be obtained.

Although the diaphragm 16 allows the water AQ to pass therethrough, the diaphragm 16 does not allow the oxygen gas bubbles and the hydrogen gas bubbles to pass therethrough. For this reason, it is preferable that the diaphragm 16 has the through-holes 17 having a hole diameter smaller than the average bubble diameter of oxygen gas bubbles 50 and the average bubble diameter of hydrogen gas bubbles 52.

Specifically, as illustrated in FIG. 5, Dh<Db is satisfied in a case where the average bubble diameters of the oxygen gas bubbles 50 and the hydrogen gas bubbles 52 are defined as Db and the hole diameter of the through-holes 17 is defined as Dh. In this case, since the water AQ passes through the through-holes 17 of the diaphragm 16, the oxygen gas and the hydrogen gas that are dissolved in the water AQ pass through the through-holes 17, but passage of the oxygen gas bubbles 50 and the hydrogen gas bubbles 52 through the through-holes 17 is suppressed.

The average hole diameter of the through-holes 17 of the diaphragm 16 is more than 0.1 μm and less than 50 μm, and preferably, more than 1 μm and less than 50 μm. In a case where the average hole diameter of the through-holes 17 is more than 0.1 μm and less than 50 μm, the water AQ passes through the through-holes 17. As a result, the oxygen gas and the hydrogen gas, which are dissolved in the water AQ, pass through the diaphragm 16, but the passage of the oxygen gas bubbles 50 and the hydrogen gas bubbles 52 is suppressed. In addition, even in a case where the oxygen gas and the hydrogen gas, which are dissolved in the water AQ, move, the amounts of the oxygen gas and the hydrogen gas dissolved within the water AQ are small. Therefore, amounts in which the oxygen gas and the hydrogen gas are mixed with each other are smaller than the amounts of the oxygen gas and the hydrogen gas to be produced. Accordingly, the oxygen gas is recovered from the first compartment 23a, and the hydrogen gas is recovered from the second compartment 23b.

The sizes of protons and ions that need to pass are far smaller than the hole diameter. In the diaphragm 16, resistance caused by the passage of the protons and the ions does not occur unlike Nafion (registered trademark). For this reason, with respect to the diaphragm 16, the larger the hole diameter, the larger the membrane thickness can be made. Therefore, this is preferable because durability is excellent.

Additionally, in polymer electrolytes such as Nafion (registered trademark), only protons and ions required for electrolysis are conducted by water molecules contained between polymers.

Meanwhile, since the diaphragm 16 has holes of such a size that bubbles of a certain size do not pass therethrough but the water AQ itself can come and go freely, many water molecules are contained within the diaphragm as compared to Nafion (registered trademark), the conductivity of protons and ions is high, and the electrolysis voltage can be suppressed to be low.

Additionally, in the related art, the purity of the hydrogen to be produced is required to be high. Therefore, the diaphragm 16 itself in which there is a concern that the purity of the hydrogen may decrease as the water AQ itself comes and goes freely cannot be conceived.

The average hole diameter of the through-holes 17 of the diaphragm 16 is determined using a microscopic observation method shown below.

In the microscopic observation method, the surface 16a of the diaphragm 16 is observed with a magnification of about 100 times to 10000 times by using an electron microscope. As a result of the observation, at least twenty through-holes 17 that are selected in descending order are imaged, circles inscribed on the through-holes 17 with respect to the irregularly-shaped through-holes 17 that appear on the captured image are drawn, and the diameters of the inscribed circle are set to the hole diameters of the through-holes 17.

A standard deviation σ of the hole diameter distribution of the at least twenty through-holes 17 is calculated, and a size that covers 3σ; is determined. The size that covers 3σ is defined as the average hole diameter of the through-holes 17 of the diaphragm 16.

In the measurement of the average hole diameter of the through-holes 17 of the diaphragm 16, “PARTICLE ANALYSIS VER. 3.5” made by NIPPON STEEL & SUMIKIN TECHNOLOGY Co., Ltd. can be used as analysis software. The minimum diameter of “PARTICLE ANALYSIS VER. 3.5” is equivalent to the diameters of the above-described inscribed circles.

Additionally, the average hole diameter of the through-holes 17 of the diaphragm 16 may be a catalog value.

The light transmittance of the diaphragm 16 is dependent on the thickness of the diaphragm 16. For this reason, it is preferable that the diaphragm 16 has a thickness d such that the light transmittance of the wavelength range having a wavelength of 380 nm to 780 nm is at least 60%. The thickness d is preferably 0.01 mm-to 0.5 mm, and, and an upper limit value of the thickness d is more preferably 0.2 mm.

The thickness d of the diaphragm 16 is a distance between the surface 16a and the back face 16b of the diaphragm 16.

It is preferable that the diaphragm 16 is formed of porous membranes having hydrophilic surfaces. That is, it is preferable that the surface 16a and the back face 16b of the diaphragm 16 are the porous membranes of the hydrophilic surfaces. Each of the surface 16a and the back face 16b of a diaphragm 16 is a face that is in contact with the oxygen gas bubbles 50 or the hydrogen gas bubbles 52.

The hydrophilic surfaces may be the property of the diaphragm 16 itself, and may be hydrophilic surfaces obtained by performing hydrophilic treatment on the diaphragm 16. For example, polytetrafluoroethylene (PTFE) is used for the diaphragm 16. Although the PTFE usually has hydrophobicity, the angle of contact with water becomes small, for example, by performing hydrophilic treatment, such as being dipped in alcohol. As a result, the PTFE exhibits the hydrophilicity.

Additionally, as the hydrophilic treatment on the diaphragm 16, there is a method of obtaining cross-linking by impregnating PVA (polyvinyl alcohol) resin. In this method, the durability of the hydrophilic treatment can be improved. In addition to this, a method shown in WO2014/021167 can also be used as the hydrophilic treatment.

The hydrophilic surfaces are defined by the angle of contact with water. The hydrophilicity and the hydrophobicity are determined on the basis of “Measurement and determination of hydrophilicity and hydrophobicity” to be described below.

By adopting the diaphragm 16 having the hydrophilic surfaces, the water AQ easily permeates into the diaphragm 16, and the through-holes 17 are no longer blocked by the oxygen gas bubbles 50 or the hydrogen gas bubbles 52. As a result, the water AQ easily passes through the through-holes 17 of the diaphragm 16. As a result, the protons and the ions in the water AQ easily pass, and the energy conversion efficiency increases. Additionally, by adopting the diaphragm 16 having the hydrophilic surfaces, the oxygen gas bubbles 50 or the hydrogen gas bubbles 52 are repelled by the surface 16a and the back face 16b of the diaphragm 16, and the oxygen gas bubbles 50 and the hydrogen gas bubbles 52 do not easily pass through the through-holes 17. Accordingly, mixing of the oxygen gas and the hydrogen gas is suppressed, and the oxygen gas and the hydrogen gas can be recovered.

Since the oxygen gas bubbles 50 and the hydrogen gas bubbles 52 do not easily pass through the through-holes 17, and simultaneously, the oxygen gas bubbles 50 and the hydrogen gas bubbles 52 do not easily adhere to the surface 16a and the back face 16b of the diaphragm 16, the oxygen gas bubbles 50 and the hydrogen gas bubbles 52 are rapidly discharged together with the flow of the water AQ. Moreover, since the oxygen gas bubbles 50 and the hydrogen gas bubbles 52 do not adhere to a diaphragm 16, the effective area of the diaphragm 16 is secured. Therefore, the energy conversion efficiency increases. Additionally, in a case where the oxygen gas bubbles 50 and the hydrogen gas bubbles 52 adhere to the diaphragm 16, there is a concern that the utilization efficiency of the light L is lowered. However, this is also suppressed, and the energy conversion efficiency increases.

An example of the transmittance including one available for the diaphragm 16 is illustrated in FIG. 6. In FIG. 6, reference sign 80 designates a Nafion (registered trademark) membrane having a thickness of 0.1 mm. Reference sign 82 designates a porous cellulose membrane. Reference sign 84 designates a hydrophilic polyethylene terephthalate (PTFE) membrane having a hole diameter of 0.1 reference sign 86 designates a hydrophilic polyethylene terephthalate (PTFE) membrane having a hole diameter of 1.0 μm, and reference sign 88 designates a hydrophilic polyethylene terephthalate (PTFE) membrane having a hole diameter of 10 μm. Reference sign 89 designates a hydrophilic PTFE membrane having a hole diameter of 10 μm, and shows a transmittance measured in the air. Reference signs 80, 82, 84, 86, and 88 other than reference sign 89 show light transmittances in a state where the membranes are immersed in the pure water having a temperature of 25° C. for one minute.

Nafion (registered trademark) used for the diaphragm from the past is not a porous membrane. The porous cellulose membrane designated by reference sign 82 has low light resistance. For this reason, as the diaphragm 16, for example, it is preferable to use the hydrophilic polyethylene terephthalate (PTFE) membranes of reference signs 84, 86, and 88 illustrated in FIG. 6. In addition, a hydrophilic PTFE membrane is seen in white in the air, and has a low transmittance as designated by reference sign 89.

In the artificial photosynthesis module 10 illustrated in FIG. 1, as described above, the diaphragm 16 is formed of a porous membrane and is made transparent in a state the diaphragm is immersed in the pure water. By supplying the water AQ into the first compartment 23a of the container 20 via the supply pipe 26a, supplying the water AQ into the second compartment 23b of the container 20 via the supply pipe 26b, and making the light L incident from the transparent member 24 side, oxygen gas is produced in the first photocatalyst layer 34 from the oxygen evolution electrode 12, the light transmitted through the oxygen evolution electrode 12 is transmitted through the diaphragm 16, and hydrogen gas is produced in the second photocatalyst layer 44 in the hydrogen evolution electrode 14 due to the transmitted light. Then, the water AQ containing the oxygen gas is discharged from the discharge pipe 28a, and the oxygen is recovered from the water AQ containing the discharged oxygen gas. Then, the water AQ containing the hydrogen gas is discharged from the discharge pipe 28b, and the hydrogen is recovered from the water AQ containing the discharged hydrogen gas. In this case, by forming the diaphragm 16 of the porous membrane as described above, the water AQ passes through the diaphragm 16 unlike an ion-exchange membrane. Accordingly, the oxygen gas and the hydrogen gas that are dissolved in the water AQ pass through the through-holes 17, but the oxygen gas bubbles 50 and the hydrogen gas bubbles 52 do not easily pass through the through-holes 17. As a result, as described above, the electrolysis efficiency, that is, the energy conversion efficiency increases.

In addition, since the water AQ in which the oxygen gas is dissolved and the water AQ in which the hydrogen gas is dissolved pass through the diaphragm 16, the hydrogen gas moves to the oxygen evolution electrode 12 side, and the oxygen gas moves to the hydrogen evolution electrode side. However, since the amount of the oxygen gas and the amount of the hydrogen gas that are dissolved in the water AQ are small as described above, mixing of the oxygen gas and the hydrogen gas is suppressed within the first compartment 23a, and mixing of the hydrogen gas and the oxygen gas is suppressed within the second compartment 23b.

In the artificial photosynthesis module 10, the oxygen evolution electrode 12 and the hydrogen evolution electrode 14 are disposed in series in the traveling direction Di of the light L. Thus, by utilizing the light L in the oxygen evolution electrode 12 and the hydrogen evolution electrode 14, the utilization efficiency of the light L can be made high, and the energy conversion efficiency is high. That is, the current density showing the water decomposition can be made high.

Additionally, in the artificial photosynthesis module 10, the energy conversion efficiency can be made high without increasing the installation area of the oxygen evolution electrode 12 and the hydrogen evolution electrode 14.

In the artificial photosynthesis module 10, as described above, the absorption end of the first photocatalyst layer 34 of the oxygen evolution electrode 12 is, for example, about 500 nm to 800 nm, and the absorption end of the second photocatalyst layer 44 of the hydrogen evolution electrode 14 is, for example, about 600 nm to 1300 nm.

Here, in a case where an absorption end of the first photocatalyst layer 34 of the oxygen evolution electrode 12 is defined as λ₁ and an absorption end of the second photocatalyst layer 44 of the hydrogen evolution electrode 14 is defined as λ₂, it is preferable that λ₁<λ₂ and λ₂−λ₁≥100 nm are satisfied. Accordingly, in a case where the light L is solar light, even in a case where light having a specific wavelength is previously absorbed by the first photocatalyst layer 34 of the oxygen evolution electrode 12 and is utilized for evolution of oxygen, the light L can be absorbed by the second photocatalyst layer 44 of the hydrogen evolution electrode 14 and can be utilized for evolution of hydrogen, and a required carrier creation amount is obtained in the hydrogen evolution electrode 14. Accordingly, the utilization efficiency of the light L can be further enhanced.

In addition, in a case where the hydrogen evolution electrode 14 and the oxygen evolution electrode 12 are electrically connected to each other, a connection form is not particularly limited and is not limited to the conducting wire 18. Additionally, the hydrogen evolution electrode 14 and the oxygen evolution electrode 12 may be electrically connected to each other, and a connection method is not particularly limited.

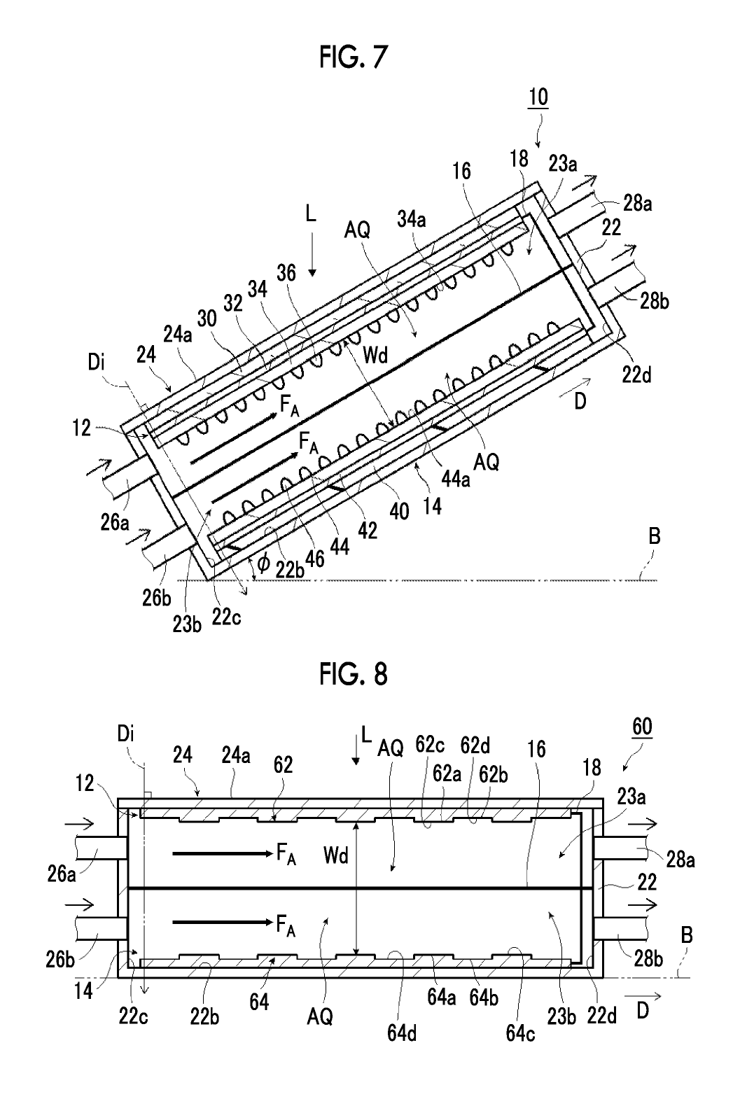

Additionally, in the artificial photosynthesis module 10, the container 20 is disposed on the horizontal plane B in FIG. 1, but may be disposed to tilt at a predetermined angle ϕ with respect to the horizontal plane B as illustrated in FIG. 7. In this case, as compared to the supply pipe 26a and the supply pipe 26b, the discharge pipe 28a and the discharge pipe 28b become high, and the oxygen gas and hydrogen gas produced are easily recovered. Additionally, the oxygen gas produced can be rapidly moved from the oxygen evolution electrode 12, and the hydrogen gas produced can be rapidly moved from the hydrogen evolution electrode 14. Accordingly, stagnation of the oxygen gas bubbles and hydrogen gas bubbles produced can be suppressed, and blocking of the light L due to the oxygen gas bubbles and hydrogen gas bubbles produced is suppressed. For this reason, the influence on the reaction efficiency of the oxygen gas and hydrogen gas produced can be reduced. In the artificial photosynthesis module 10, the inclination angle thereof is not particularly limited, and solar light can be efficiently utilized by inclining the module 10 to an incidence direction of the solar light according to the latitude.

As illustrated in FIG. 7, in a case where the module 10 is inclined at the angle ϕ with respect to the horizontal plane B, the light L is not incident perpendicularly to the surface 24a of the transparent member 24. However, in the oxygen evolution electrode 12, the first photocatalyst layer 34 is provided on the side opposite to the incidence side of the light L and the first substrate 30. Also in the artificial photosynthesis module 10 inclined at the angle ϕ illustrated in FIG. 7, the traveling direction Di of the light L is made the same as that in FIG. 1.

Hereinafter, the oxygen evolution electrode 12 that is an example of the first electrode, and the hydrogen evolution electrode 14 that is an example of the second electrode will be described.

First, photocatalyst layers and co-catalysts suitable for the oxygen evolution electrode 12 will be described.

<Photocatalyst Layer of Oxygen Evolution Electrode>

As optical semiconductors constituting the photocatalyst layers, well-known photocatalysts may be used, and optical semiconductors containing at least one kind of metallic element are used.

Among these, from a viewpoint of more excellent onset potential, higher photocurrent density, or more excellent durability against continuous irradiation, as metallic elements, Ti, V, Nb, Ta, W, Mo, Zr, Ga, In, Zn, Cu, Ag, Cd, Cr, or Sn is preferable, and Ti, V, Nb, Ta, or W is more preferable. Additionally, the optical semiconductors include oxides, nitrides, oxynitrides, sulfides, selenides, and the like, which contain the above metallic elements.

Additionally, the optical semiconductors are usually contained as a main component in the photocatalyst layers. The main component means that the optical semiconductors are equal to or more than 80% by mass with respect to the total mass of the second photocatalyst layer, and preferably equal to or more than 90% by mass. Although an upper limit of the main component is not particularly limited, the upper limit is 100% by mass.

Specific examples of the optical semiconductors may include, for example, oxides, such as Bi₂WO₆, BiVO₄, BiYWO₆, In₂O₃(ZnO)₃, InTaO₄, and InTaO₄:Ni (“optical semiconductor: M” shows that the optical semiconductors are doped with M. The same applies below), TiO₂:Ni, TiO₂:Ru, TiO₂Rh, and TiO₂: Ni/Ta (“optical semiconductor: M1/M2” shows that the optical semiconductors are doped with M1 and M2. The same applies below), TiO₂:Ni/Nb, TiO₂:Cr/Sb, TiO₂:Ni/Sb, TiO₂:Sb/Cu, TiO₂:Rh/Sb, TiO₂:Rh/Ta, TiO₂:Rh/Nb, SrTiO₃:Ni/Ta, SrTiO₃:Ni/Nb, SrTiO₃:Cr, SrTiO₃:Cr/Sb, SrTiO₃:Cr/Ta, SrTiO₃:Cr/Nb, SrTiO₃:Cr/W, SrTiO₃:Mn, SrTiO₃:Ru, SrTiO₃:Rh, SrTiO₃:Rh/Sb, SrTiO₃:Ir, CaTiO₃:Rh, La₂Ti₂O₇:Cr, La₂Ti₂O₇:Cr/Sb, La₂Ti₂O₇:Fe, PbMoO₄:Cr, RbPb₂Nb₃O₁₀, HPb₂Nb₃O₁₀, PbBi₂Nb₂O₉, BiVO₄, BiCu₂VO₆, BiSn₂VO₆, SnNb₂O₆, AgNbO₃, AgVO₃, AgLi_{1/3}Ti_{2/3}O₂, AgLi_{1/3}Sn_{2/3}O₂, WO₃, BaBi₁₋ₓInₓO₃, BaZr₁₋ₓSnₓO₃, BaZr₁₋ₓGeₓO₃, and BaZr₁₋ₓSiₓO₃, oxynitrides, such as LaTiO₂N, Ca_{0.25}La_{0.75}TiO_{2.25}N_{0.75}, TaON, CaNbO₂N, BaNbO₂N, CaTaO₂N, SrTaO₂N, BaTaO₂N, LaTaO₂N, Y₂Ta₂O₅N₂, (Ga₁₋ₓZnₓ)(N₁₋ₓOₓ), (Zn₁₊ₓGe)(N₂Oₓ) (x represents a numerical value of 0 to 1), and TiNₓO_{y}F_{z}, nitrides, such as NbN and Ta₃N₅, sulfides, such as CdS, selenide, such as CdSe, oxysulfide compounds (Chemistry Letters, 2007, 36, 854 to 855) including Ln₂Ti₂S₂O₅ (Ln: Pr, Nd, Sm, Gd, Tb, Dy, Ho, and Er), La, and In, the optical semiconductors are not limited to the materials exemplified here.

Among these, as the optical semiconductors, BaBi₁₋ₓInₓO₃, BaZr₁₋ₓSnₓO₃, BaZr₁₋ₓGeₓO₃, BaZr₁₋ₓSiₓO₃, NbN, TiO₂, WO₃, TaON, BiVO₄, or Ta₃N₅, AB(O, N)₃ {A=Li, Na, K, Rb, Cs, Mg, Ca, Sr, Ba, La, or Y, B=Ta, Nb, Sc, Y, La, or Ti} having a perovskite structure; solid solutions including AB(O, N)₃ having the above-described perovskite structure as a main component; or doped bodies including TaON, BiVO₄, Ta₃N₅, or AB(O, N)₃ having the perovskite structure as a main component are preferable.

The shape of the optical semiconductors included in the photocatalyst layers are not particularly limited, and include a film shape, a columnar shape, a particle shape, and the like.

In a case where the optical semiconductors are particulate, the particle diameter of primary particles thereof is not particularly limited. However, usually, the particle diameter is preferably 0.01 μm or more, and more preferably, 0.1 μm or more, and usually, the particle diameter is preferably 10 μm or less and more preferably, 2 μm or less.

The above-described particle diameter is an average particle diameter, and is obtained by measuring the particle diameters (diameters) of any 100 optical semiconductors observed by a transmission electron microscope or a scanning electron microscope and arithmetically averaging these particle diameters. In addition, major diameters are measured in a case where the particle shape is not a true circle.

In a case where the optical semiconductors are columnar, it is preferable that the columnar optical semiconductors extend in a normal direction of the surface of the conductive layer. Although the diameter of the columnar optical semiconductors is particularly limited, usually, the diameter is preferably 0.025 μm or more, and more preferably, 0.05 μm or more, and usually, the diameter is preferably 10 μm or less and more preferably, 2 μm or less.

The above-described diameter is an average diameter and is obtained by measuring the diameters of any 100 columnar optical semiconductors observed by the transmission electron microscope (Device name: H-8100 of Hitachi High Technologies Corporation) or the scanning electron microscope (Device name: SU-8020 type SEM of Hitachi High Technologies Corporation) and arithmetically averaging the diameters.

Although the thickness of the photocatalyst layers is not limited, in the case of an oxide or a nitride, it is preferable that the thickness is 300 nm or more and 2 μm or less. In addition, the optimal thickness of the photocatalyst layers is determined depending on the penetration length of the light L or the diffusion length of excited carriers.

Here, in many materials of the photocatalyst layers containing BiVO4 used well as a material of the photocatalyst layers, the reaction efficiency is not the maximum at such a thickness that all light having absorbable wavelengths can be utilized. In a case where the thickness is large, it is difficult to transport the carriers generated in a location distant from a film surface without deactivating the carriers up to the film surface, due to the problems of the lifespan and the mobility of the carriers. For that reason, even in a case where the film thickness is increased, an expected electric current cannot be taken out.

Additionally, in a particle transfer electrode that is used well in a particle system, the larger the particle diameter, the rougher the electrode film becomes. As the thickness, that is, the particle diameter increases, the film density decreases, and an expected electric current cannot be taken out. The electric current can be taken out in a case where the thickness of the photocatalyst layers is 300 nm or more and 2 μm or less.

By acquiring a scanning electron microscope image of a cross-sectional state of a photocatalyst electrode, the thickness of the photocatalyst layers can be obtained from the acquired image.

The above-described method for forming the photocatalyst layers is not limited, and well-known methods (for example, a method for depositing particulate optical semiconductors on a substrate) can be adopted. The formation methods include, specifically, vapor phase film formation methods, such as an electron beam vapor deposition method, a sputtering method, and a chemical vapor deposition (CVD) method; a transfer method described in Chem. Sci., 2013, 4, and 1120 to 1124; and a method described in Adv. Mater., 2013, 25, and 125 to 131.

In addition, the other layer, for example, an adhesive layer may be included between a substrate and a photocatalyst layer as needed.

<Co-Catalyst of Oxygen Evolution Electrode>

As the co-catalysts, noble metals and transition metal oxides are used. The co-catalysts are carried and supported using a vacuum vapor deposition method, a sputtering method, an electrodeposition method, and the like. In a case where the co-catalysts are formed with a set film thickness of, for example, about 1 nm to 5 nm, the co-catalysts are not formed as films but become island-like.

As the first co-catalyst 36, for example, single substances constituted with Pt, Pd, Ni Au, Ag, Ru Cu, Co, Rh, Ir, Mn, Fe, or the like, alloys obtained by combining these single substances, and oxides of these single substances, for example, FeOx, CoOx such as CoO, NiOx, and RuO₂, may be used.

Next, the second conductive layer 42, the second photocatalyst layer 44, and the second co-catalyst 46 of the hydrogen evolution electrode 14 will be described.

The second substrate 40 of the hydrogen evolution electrode 14 illustrated in FIG. 4 supports the second photocatalyst layer 44, and is configured to have an electrical insulating property. Although the second substrate 40 is not particularly limited, for example, a soda lime glass substrate or a ceramic substrate can be used. Additionally, a substrate in which an insulating layer is formed on a metal substrate can be used as the second substrate 40. Here, as the metal substrate, a metal substrate, such as an Al substrate or a steel use stainless (SUS) substrate, or a composite metal substrate, such as a composite Al substrate formed of a composite material of Al, and for example, other metals, such as SUS, is available. In addition, the composite metal substrate is also a kind of the metal substrate, and the metal substrate and the composite metal substrate are collectively and simply referred to as the metal substrate. Moreover, a metal substrate with an insulating film having an insulating layer formed by anodizing a surface of the Al substrate or the like can also be used as the second substrate 40. The second substrate 40 may be flexible or may not be flexible. In addition, in addition to the above-described substrates, for example, glass plates, such as high strain point glass and non-alkali glass, or a polyimide material can also be used as the second substrate 40.

The thickness of the second substrate 40 is not particularly limited, may be about 20 μm to 2000 μm, is preferably 100 μm to 1000 μm, and is more preferably 100 μM to 500 μm. In addition, in a case where one including a copper indium gallium (di) selenide (CIGS) compound semiconductor is used as the second photocatalyst layer 44, photoelectric conversion efficiency is improved in a case where alkali ions (for example, sodium (Na) ions: Na+) are supplied to the second substrate 40 side. Thus, it is preferable to provide an alkali supply layer that supplies the alkali ions to a surface 40a of the second substrate 40. In addition, in a case where an alkali metal is included in the constituent elements of the second substrate 40, the alkali supply layer is unnecessary.

<Conductive Layer of Hydrogen Evolution Electrode>

The second conductive layer 42 traps and transports the carriers generated in the second photocatalyst layer 44. Although the second conductive layer 42 is not particularly limited as long as the conductive layer has conductivity, the second conductive layer 42 is formed of, for example, metals, such as Mo, Cr, and W, or combinations thereof. The second conductive layer 42 may have a single-layer structure, or may have a laminate structure, such as a two-layer structure. Among these, it is preferable that the second conductive layer 42 is formed of Mo. It is preferable that the second conductive layer 42 has a thickness of 200 nm to 1000 nm.

<Photocatalyst Layer of Hydrogen Evolution Electrode>

The second photocatalyst layer 44 generates carriers by light absorption, and a conduction band lower end there is closer to a base side rather than a redox potential (H₂/H⁺) at which water is decomposed to produce hydrogen. Although the second photocatalyst layer 44 has p-type conductivity of generating holes and transporting the holes to the second conductive layer 42, it is also preferable to laminate the material having n-type conductivity on the surface 44a of the second photocatalyst layer 44 to form a pn junction. The thickness of the second photocatalyst layer 44 is preferably 500 nm to 3000 nm.

The optical semiconductors constituting one having p-type conductivity are optical semiconductors containing at least one kind of metallic element. Among these, from a viewpoint of more excellent onset potential, higher photocurrent density, or more excellent durability against continuous irradiation, as metallic elements, Ti, V, Nb, Ta, W, Mo, Zr, Ga, In, Zn, Cu, Ag, Cd, Cr, or Sn is preferable, and Ga, In, Zn, Cu, Zr, or Sn is more preferable.

Additionally, the optical semiconductors include oxides, nitrides, oxynitrides, (oxy)chalcogenides, and the like including the above-described metallic elements, and is preferably constituted of GaAs, GaInP, AlGaInP, CdTe, CuInGaSe, CIGS compound semiconductors having a chalcopyrite crystal structure, or CZTS compound semiconductors, such as Cu₂ZnSnS₄.

It is particularly preferable that the optical semiconductors are constituted of the CIGS compound semiconductors having a chalcopyrite crystal structure or the CZTS compound semiconductors, such as Cu₂ZnSnS₄. The CIGS compound semiconductor layer may be constituted of CuInSe₂ (CIS), CuGaSe₂ (CGS), or the like as well as Cu(In, Ga)Se₂ (CIGS). Moreover, the CIGS compound semiconductor layer is may be configured by substituting all or part of Se with S.

In addition, as methods for forming the CIGS compound semiconductor layer, 1) a multi-source vapor deposition method, 2) a selenide method, 3) a sputtering method, 4) a hybrid sputtering method, 5) a mechanochemical process method, and the like are known.

Other methods for forming the CIGS compound semiconductor layer include a screen printing method, a proximity sublimating method, a metal organic chemical vapor deposition (MOCVD) method, a spraying method (wet film formation method), and the like. For example, in the screen printing method (wet film formation method), the spraying method (wet film formation method), or the like, crystal having a desired composition can be obtained by forming a particulate film including an 11 group element, a 13 group element, and a 16 group element on a substrate, and executing thermal decomposition processing (may be thermal decomposition processing in a 16 group element atmosphere in this case) or the like (JP1997-074065A (JP-H09-074065A), JP1997-074213A (JP-H09-074213A), or the like). Hereinafter, the CIGS compound semiconductor layer is also simply referred to as a CIGS layer.

In a case where the material having n-type conductivity is laminated on the surface 44a of the second photocatalyst layer 44 as described above, the Pn junction is formed.

It is preferable that the material having n-type conductivity is formed of one including metal sulfide including at least one kind of metallic element selected from a group consisting of, for example, Cd, Zn, Sn, and In, such as CdS, ZnS, Zn(S, O), and/or Zn (S, O, OH), SnS, Sn(S, O), and/or Sn(S, O, OH), InS, In (S, O), and/or In (S, O, OH). It is preferable that the film thickness of a layer of the material having n-type conductivity is 20 nm to 100 nm. The layer of the material having n-type conductivity is formed by, for example, a chemical bath deposition (CBD) method.

The configuration of the second photocatalyst layer 44 is not particularly limited as long as second photocatalyst layer 44 is formed of an inorganic semiconductor and can obtain hydrogen gas, such as causing a photocomposition reaction of water to produce hydrogen gas.

For example, photoelectric conversion elements used for solar battery cells that constitute a solar battery are preferably used. As such photoelectric conversion elements, in addition to those using the above-described CIGS compound semiconductors or CZTS compound semiconductors such as Cu₂ZnSnS₄, thin film silicon-based thin film type photoelectric conversion elements, CdTe-based thin film type photoelectric conversion elements, dye-sensitized thin film type photoelectric conversion elements, or organic thin film type photoelectric conversion elements can be used.

<Co-Catalyst of Hydrogen Evolution Electrode>

As the second co-catalyst 46, it is preferable that, for example, Pt, Pd, Ni, Ag, Ru, Cu, Co, Rh, Ir, Mn, and RuO₂ are used.

A transparent conductive layer (not illustrated) may be provided between the second photocatalyst layer 44 and the second co-catalyst 46. The transparent conductive layer needs a function of electrically connecting the second photocatalyst layer 44 and the second co-catalyst 46 to each other, transparency, water resistance, and water impermeability are also required for the transparent conductive layer, and the durability of the hydrogen evolution electrode 14 is improved by the transparent conductive layer.

It is preferable that the transparent conductive layer is formed of, for example, metals, conductive oxides (of which the overpotential is equal to or lower than 0.5 V), or composites thereof. The transparent conductive layer is appropriately selected in conformity with the absorption wavelength of the second photocatalyst layer 44. Transparent conductive films formed of ZnO that is doped with indium tin oxide (ITO), fluorine-doped tin oxide (FTO), Al, B, Ga, In, or the like, or IMO (In₂O₃ doped with Mo) can be used for the transparent conductive layer. The transparent conductive layer may have a single-layer structure, or may have a laminate structure, such as a two-layer structure. Additionally, the thickness of the transparent conductive layer is not particularly limited, and is preferably 30 nm to 500 nm.

In addition, although methods for forming the transparent conductive layer are not particularly limited, a vacuum film formation method is preferable. The transparent conductive layer can be formed by vapor phase film formation methods, such as an electron beam vapor deposition method, a sputtering method, and a chemical vapor deposition (CVD) method.

Additionally, instead of the transparent conductive layer, a protective film that protects the second co-catalyst 46 may be provided on the surface of the second co-catalyst 46.

The protective film is configured in conformity with the absorption wavelength of the second co-catalyst 46. For example, oxides, such as TiO₂, ZrO₂, and Ga₂O₃, are used for the protective film. In a case where the protective film is an insulator, for example, the thickness thereof is 5 nm to 50 nm, and film formation methods, such as an atomic layer deposition (ALD) method, are selected. In a case where the protective film is conductive, for example, the protective film has a thickness of 5 nm to 500 nm, and may be formed by a sputtering method and the like in addition to the atomic layer deposition (ALD) method and a chemical vapor deposition (CVD) method. The protective film can be made thicker in a case where the protective film is a conductor than in a case where the protective film is insulating.

Although both of the oxygen evolution electrode 12 and the hydrogen evolution electrode 14 have a flat plate shape as a whole, the invention is not limited to this, and may be configured to have through-holes that penetrate in a thickness direction of each electrodes. In a case where the through-holes are provided, both of the oxygen evolution electrode 12 and the hydrogen evolution electrode 14 are not limited to the through-holes that penetrate in the thickness direction of the electrode, and electrode configurations may be mesh-like electrodes. In this case, in the oxygen evolution electrode 12, the entire electrode may be a mesh-like electrode. For example, the first substrate 30 may be formed of a mesh, or a sheet body having a plurality of through-holes. In the hydrogen evolution electrode 14, the entire electrode may be a mesh-like electrode. For example, the second substrate 40 may be formed of a mesh, or a sheet body having a plurality of through-holes.

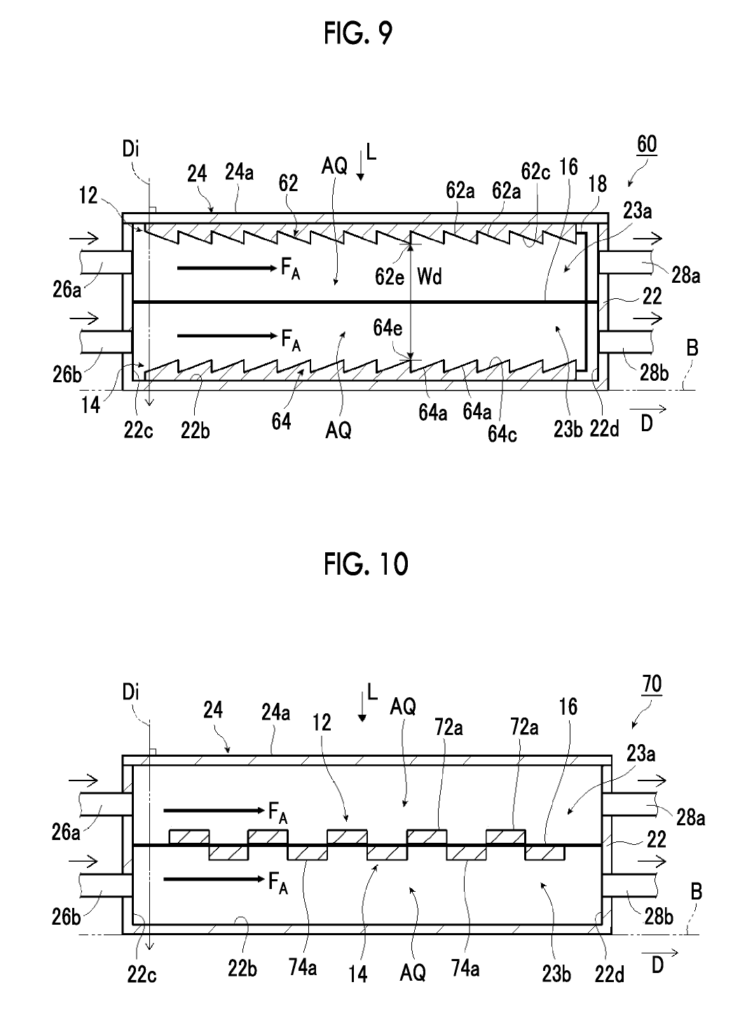

FIG. 8 is a schematic cross-sectional view illustrating a third example of the artificial photosynthesis module of the embodiment of the invention. FIG. 9 is a schematic cross-sectional view illustrating a fourth example of the artificial photosynthesis module of the embodiment of the invention.

In FIGS. 8 and 9, the same components as those of the artificial photosynthesis module illustrated in FIG. 1 will be designated by the same reference signs, and the detailed description thereof will be omitted. In the third example and the fourth example of an artificial photosynthesis module, similarly to the first example of the above-described artificial photosynthesis module, the raw material fluid is water, the first fluid is oxygen, and the second fluid is hydrogen.

An artificial photosynthesis module 60 illustrated in FIG. 8 has the same configuration as the artificial photosynthesis module 10 illustrated in FIG. 1 except that the configurations of the oxygen evolution electrode 12 and the hydrogen evolution electrode 14 are different.

In the artificial photosynthesis module 60 illustrated in FIG. 8, the cross-sectional shapes of the oxygen evolution electrode 12 and the hydrogen evolution electrode 14 are illustrated. However, the configuration of the oxygen evolution electrode 12 and the configuration of the hydrogen evolution electrode 14 are the same as those of the artificial photosynthesis module 10 illustrated in FIG. 1.

In the artificial photosynthesis module 60, the oxygen evolution electrode 12 and the hydrogen evolution electrode 14 is provided with at least one projecting part that projects with respect to the diaphragm 16. A plurality of the projecting parts may be provided in the flow direction F_{A} of the water AQ.

The projecting parts may have a periodic structure in which the heights thereof from surfaces change periodically in the flow direction F_{A} of the water AQ.

In the oxygen evolution electrode 12, for example, protrusions 62a and recesses 62b, which are a projecting part 62, are alternately disposed with respect to the direction D. Additionally, in the hydrogen evolution electrode 14, for example, protrusions 64a and recesses 64b, which are a projecting part 64, are alternately disposed with respect to the direction D.

The protrusions 62a and the recesses 62b of the oxygen evolution electrode 12 can be obtained, for example, by forming irregular grooves in the surface of the first substrate 30 through machining, such as cutting. The protrusions 64a and the recess 64b of the hydrogen evolution electrode 14 can also be formed in the surface of the second substrate 40 through machining, such as cutting, as described above, similarly to the oxygen evolution electrode 12.

In the oxygen evolution electrode 12, as illustrated in FIG. 8, the protrusions 62a and the recesses 62b are repeatedly provided in the flow direction F_{A} of the water AQ, and have a rectangular irregular structure. A surface 62c of each protrusion 62a is a face parallel to the flow direction F_{A} of the water AQ. A surface 62d of each recess 62b is a face parallel to the flow direction F_{A} of the water AQ.

In the hydrogen evolution electrode 14, as illustrated in FIG. 8, the protrusions 64a and the recesses 64b are repeatedly provided in the flow direction F_{A} of the water AQ, and have a rectangular irregular structure. A surface 64c of each protrusion 64a is a face parallel to the flow direction F_{A} of the water AQ. A surface 64d of each recess 64b is a face parallel to the flow direction F_{A} of the water AQ.

The protrusions 62a are disposed on the upstream side in the flow direction F_{A}. However, the invention is not limited to this, the protrusions 62a and the recesses 62b may be replaced with each other, and the recesses 62b may be disposed on the upstream side in the flow direction F_{A}.

The numbers of protrusions 62a and recesses 62b in the projecting part 62 may be at least one, respectively, and the number of protrusions 62a and the number of recesses 62b may be the same as each other or may be different from each other. Additionally, the length of each protrusion 62a in the flow direction F_{A} of the water AQ and the length of each recess 62b in the flow direction F_{A} of the water AQ may be the same as each other or may be different from each other. The length of the protrusion 62a in the flow direction F_{A} of the water AQ is the pitch of the projecting part 62 in the flow direction F_{A} of the water AQ. It is preferable that the length is 1.0 mm or more and 20 mm or less.

In a case where the length of the protrusion 62a in the flow direction F_{A} of the water AQ is 1.0 mm or more and 20 mm or less, a high electrolytic current can be obtained.

Although the length of the recess 62b in the flow direction F_{A} of the water AQ is not particularly limited, the length of the recess 62b may be the same as the length of the protrusion 62a in flow direction F_{A} of the water AQ, for example, may be 1.0 mm or more and 20 mm or less.

Additionally, it is preferable that the height of the projecting part 62 from the surface 62d of the recess 62b is 0.1 mm or more and 5.0 mm or less. One in which the height of the irregularities, that is, the height h is 0.1 mm or more is the projecting part 62. The above-described height is a distance from the surface 62d of the recess 62b to the surface 62c of the protrusion 62a. In a case where the height is 0.1 mm or more and 5.0 mm or less, a high electrolytic current can be obtained.

It is preferable that an interval Wd between the oxygen evolution electrode 12 and the hydrogen evolution electrode 14 is narrower because efficiency becomes higher as the interval is narrower. Specifically, it is preferable that the interval Wd is 1 mm to 20 mm. The interval Wd is a distance from the surface 62c of the protrusion 62a of the oxygen evolution electrode 12 to and the surface 64c of the protrusion 64a of the hydrogen evolution electrode 14.

Additionally, the length of each of the protrusions 62a and 64a in the flow direction F_{A} of the water AQ, the length of each of the recesses 62b and 64b in the flow direction F_{A} of the water AQ, and a method of measuring the above-described height will be described. First, a digital image is acquired from a side face direction of the projecting part 64, the digital image is taken into a personal computer and displayed on a monitor, lines of locations corresponding to the above-described lengths and the above-described height are drawn on the monitor, and the lengths of the respective lines are determined. Accordingly, the above-described lengths and the above-described height can be obtained.

In addition, in the oxygen evolution electrode 12 and the hydrogen evolution electrode 14, the above-described lengths and the above-described height may be the same as each other or may be different from each other.

It is preferable that the protrusions 62a of the projecting part 62 or the protrusions 64a of the projecting part 64 are provided within a range of 50% or more of the area of the surface on which the projecting part 62 or 64 are provided. For example, it is preferable that the protrusions 62a or the protrusions 64a are provided to be equal to or more than half of the total length of the oxygen evolution electrode 12 or the hydrogen evolution electrode 14.

In this case, it is preferable that the total of the lengths of the protrusions 62a or 64a is more than half of a length Wc. For this reason, the protrusions 62a or the protrusions 64a can be provided within a range of 50% or more of the area of the surface on which the projecting part 62 or 64 is provided by making the total number of the protrusions 62a or 64a more than the total number of the recesses 62b or 64b.

In the artificial photosynthesis module 60, in a case where the water AQ is made to flow in a direction parallel to the direction D, the flow direction F_{A} of the water AQ is the direction parallel to the direction D and is a direction crossing the protrusions 62a or 64a and the recesses 62b or 64b.

In the artificial photosynthesis module 60, by making the oxygen evolution electrode 12 and the hydrogen evolution electrode 14 have the rectangular irregular structure as described above, turbulence occurs in the flow of the water AQ, the effect of peeling off the oxygen gas bubbles and the hydrogen gas bubbles adhering to the diaphragm 16 is obtained, and a decrease in the utilization efficiency of the light L is suppressed. Accordingly, the electrolysis voltage decreases and the energy conversion efficiency increases.

Additionally, as in the artificial photosynthesis module 60 illustrated in FIG. 9, both the projecting part 62 of the oxygen evolution electrode 12 and the projecting part 64 of the hydrogen evolution electrode 14 may have the periodic structure in which the protrusions 62a and 64a of which the surfaces 62c and 64c are inclined faces are continuously disposed in the flow direction F_{A} of the water AQ, and the heights thereof from surfaces change periodically in the flow direction F_{A} of the water AQ. Even in this case, similarly to the above-described rectangular irregular structure, turbulence occurs in the flow of the water AQ, the effect of peeling off the oxygen gas bubbles and the hydrogen gas bubbles adhering to the diaphragm 16 is obtained, and a decrease in the utilization efficiency of the light L is suppressed. Accordingly, the electrolysis voltage decreases and the energy conversion efficiency increases.

Although the inclination angle of each inclined face is 90° or less with respect to the flow direction F_{A} of the water AQ, the inclination angle is not limited to this. The inclination angle may be larger than 90°. In this case, the inclined face is inclined against the flow direction F_{A} of the water AQ.

In a case where the inclination angle of the inclined face is large, the flow resistance of the water AQ increases, and the flow rate thereof becomes low. The energy consumption for supplying the water AQ increases in a case where the flow rate of the water AQ is increased, and the energy loss is increased in a case where the flow rate of the water AQ is increased. For this reason, the total energy conversion efficiency of the artificial photosynthesis module 60 decreases.

Thus, the inclination angle is preferably 5° or more and 45° or less, and more preferably, an upper limit value thereof is 30° or less. A lower limit value of the inclination angle is, for example, 5°. In a case where the inclination angle is 45° or less, a high electrolytic current can be obtained.

It is preferable that the interval Wd between the oxygen evolution electrode 12 and the hydrogen evolution electrode 14 is narrower because efficiency becomes higher. Specifically, it is preferable that the interval Wd is 1 mm to 20 mm. The interval Wd is a distance between a maximum projecting end 62e of the surface 62c of the protrusion 62a of the oxygen evolution electrode 12 and a maximum projecting end 64e of the surface 64c of the protrusion 64a of the hydrogen evolution electrode 14.

Additionally, the inclination angle of the oxygen evolution electrode 12 or the hydrogen evolution electrode 14 is obtained by acquiring a digital image from a side face direction of the oxygen evolution electrode 12 or the hydrogen evolution electrode 14, taking the digital image into a personal computer, displaying the digital image on a monitor, drawing a horizontal line on the monitor, and determining an angle formed between the horizontal line and the surfaces of the inclined faces of the oxygen evolution electrode 12 or the hydrogen evolution electrode 14.

In addition, in the oxygen evolution electrode 12 and the hydrogen evolution electrode 14, the sizes of the projecting parts 62 and 64 may be the same as each other or may be different from each other. Any one of the oxygen evolution electrode 12 and the hydrogen evolution electrode 14 may a so-called solid electrode having no projecting part.

The entire surface of at least one of the oxygen evolution electrode 12 or the hydrogen evolution electrode 14 may be inclined such that the thickness increases with respect to the flow direction F_{A} of the water AQ. In this case, the inclination angles of the oxygen evolution electrode 12 and the hydrogen evolution electrode 14 may be the same as each other or may be different from each other.

On the contrary, the entire surface of at least one of the oxygen evolution electrode 12 or the hydrogen evolution electrode 14 may be inclined such that the thickness decreases with respect to the flow direction F_{A} of the water AQ. Even in this case, the inclination angles of the oxygen evolution electrode 12 and the hydrogen evolution electrode 14 may be the same as each other or may be different from each other. In any of the above-described cases, it is preferable that each inclination angle is 5° or more and 45° or less.

In addition, in all the artificial photosynthesis modules 10 illustrated in FIGS. 1 and 7 and the artificial photosynthesis modules 60 illustrated in FIGS. 8 and 9, the oxygen evolution electrode 12 and the hydrogen evolution electrode 14 are disposed in this order from the incidence side of the light L. However, the invention is not limited to this configuration, and the hydrogen evolution electrode 14 and the oxygen evolution electrode 12 may be disposed in this order.

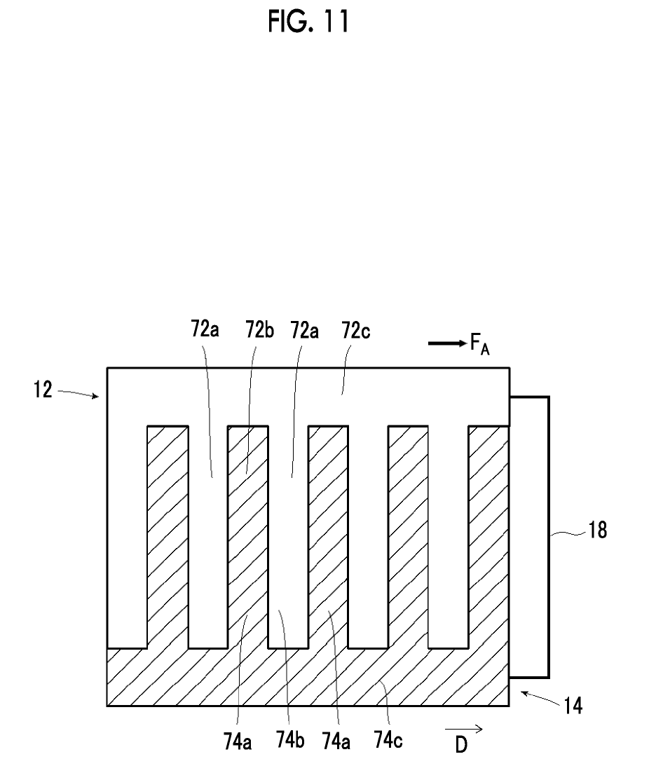

In addition, the oxygen evolution electrode 12 and the hydrogen evolution electrode 14 may have a comb structure illustrated in FIGS. 10 and 11.

Here, FIG. 10 is a schematic cross-sectional view illustrating a fifth example of the artificial photosynthesis module of the embodiment of the invention, and FIG. 11 is a schematic plan view illustrating an electrode configuration of the fifth example of the artificial photosynthesis module of the embodiment of the invention.

In FIGS. 10 and 11, the same components as those of the artificial photosynthesis module illustrated in FIG. 1 will be designated by the same reference signs, and the detailed description thereof will be omitted. In addition, illustration of the diaphragm 16 is omitted in FIG. 11.

An artificial photosynthesis module 70 illustrated in FIG. 10 has the same configuration as the artificial photosynthesis module 10 illustrated in FIG. 1 except that the configurations of the oxygen evolution electrode 12 and the hydrogen evolution electrode 14 are different.

The oxygen evolution electrode 12 and the hydrogen evolution electrode 14 of the artificial photosynthesis module 70 that is illustrated in FIG. 10 have the same configuration as that of the oxygen evolution electrode 12 and the hydrogen evolution electrode 14 of the artificial photosynthesis module 10 including the layer configuration except that comb electrodes are provided. In this case, the first photocatalyst layer 34 (refer to FIG. 3) of the oxygen evolution electrode 12 is provided on the incidence side of the light L. The second photocatalyst layer 44 (refer to FIG. 4) of the hydrogen evolution electrode 14 is also provided on the incidence side of the light L.

As illustrated in FIG. 11, the oxygen evolution electrode 12 is constituted of, for example, a flat plate, and has an oblong first electrode part 72a, an oblong first gap 72b, and a base part 72c to which a plurality of the first electrode parts 72a are connected, and the first electrode part 72a and the first gap 72b are alternately disposed in the direction D. The plurality of first electrode parts 72a are integral with the base part 72c, and the plurality of first electrode parts 72a are electrically connected to each other, respectively.

The hydrogen evolution electrode 14 is constituted of, for example, a flat plate, and has an oblong second electrode part 74a, an oblong second gap 74b, and a base part 74c to which a plurality of the second electrode parts 74a are connected, and the second electrode part 74a and the second gap 74b are alternately disposed in the direction D. The plurality of second electrode parts 74a are integral with the base part 74c, and the plurality of second electrode parts 74a are electrically connected to each other, respectively.

An arrangement direction of the first electrode parts 72a and an arrangement direction of the second electrode parts 74a are made parallel to the direction D.

As illustrated in FIG. 11, both the oxygen evolution electrode 12 and the hydrogen evolution electrode 14 are comb-type electrodes, and the first electrode parts 72a and the second electrode parts 74a are equivalent to comb teeth of the comb electrodes. Both of the oxygen evolution electrode 12 and the hydrogen evolution electrode 14 are referred to as comb-type electrodes.

In a case where the oxygen evolution electrode 12 and the hydrogen evolution electrode 14 are seen from the incidence side of the light L, the first electrode part 72a is disposed in the second gap 74b, and the second electrode part 74a is disposed in the first gap 72b. In this case, a gap may be present between the second gap 74b and the first electrode part 72a in the direction D.

In the artificial photosynthesis module 70, the flow direction F_{A} of the water AQ is a direction parallel to the direction D, and the water AQ flows so as to cross the first electrode part 72a and the second electrode part 74a.

Additionally, in the artificial photosynthesis module 70, the oxygen evolution electrode 12 and the hydrogen evolution electrode 14 are also disposed in this order from the incidence side of the light L. However, the invention is not limited to this configuration and the hydrogen evolution electrode 14 and the oxygen evolution electrode 12 may be disposed in this order from the incidence side of the light L. For this reason, there is also a case where the oxygen evolution electrode 12 is disposed on the side of the diaphragm 16 opposite to the incidence side of the light L. Here, an absorption end of the oxygen evolution electrode 12 is, for example, about 400 nm to 800 nm. Then, it is preferable that the diaphragm 16 has a high transmittance even in an ultraviolet region of which the wavelength is near 400 nm.

In the artificial photosynthesis module 70 having the comb electrode configuration, the first electrode part 72a of the oxygen evolution electrode 12 and the second electrode part 74a of the hydrogen evolution electrode 14 may be inclined in the flow direction F_{A} of the water AQ, respectively. In this case, the inclination angle is preferably 5° or more and 45° or less, and more preferably, an upper limit value thereof is 30° or less. In a case where the inclination angle is 5° or more and 45° or less, a high electrolytic current can be obtained.

In addition, in a case where the first electrode part 72a of the oxygen evolution electrode 12 and the second electrode part 74a of the hydrogen evolution electrode 14 have a large inclination angle, the flow resistance of the water AQ increases, and the flow rate becomes low. The energy consumption for supplying the water AQ increases in a case where the flow rate of the water AQ is increased, and the energy loss is increased in a case where the flow rate of the water AQ is increased. For this reason, the total energy conversion efficiency of the artificial photosynthesis module 70 decreases.

In addition, an inclination angle of the first electrode part 72a and an inclination angle of the second electrode part 74a may be the same angles or may be different angles. The first electrode part 72a of the oxygen evolution electrode 12 and the second electrode part 74a of the hydrogen evolution electrode 14 may be inclined in the flow direction F_{A} or may be inclined to the side opposite to the flow direction F_{A}.

Additionally, any one of the first electrode part 72a of the oxygen evolution electrode 12 and the second electrode part 74a of the hydrogen evolution electrode 14 may have the inclination angle of 0°, that is, may not be inclined. By inclining at least one electrode part, as compared to the flat configuration in which the electrode parts of both the electrodes are not inclined, the electrolytic current becomes high, and excellent energy conversion efficiency can be obtained.

Since the inclination angle can be measured by the same method as the inclination angle of the above-described artificial photosynthesis module 60 illustrated in FIG. 9, the detailed description thereof will be omitted.

The comb electrode is not constituted of the flat plate, but may be constituted of a polygonal surface, a curved face, or a combination of a planar surface and the curved face. Even in this case, at least one of the oxygen evolution electrode or the hydrogen evolution electrode is not constituted of a planar surface, but may be constituted of the polygonal surface, the curved face, or the combination of the planar surface and the curved face as described above.

Additionally, the oxygen evolution electrode 12 and the hydrogen evolution electrode 14 may have a flatly placed form in addition to the comb electrode structure. The flatly placed form is, for example, a form in which a flat plate-shaped oxygen evolution electrode 12 and a flat plate-shaped hydrogen evolution electrode 14 are disposed in parallel with the diaphragm 16 interposed therebetween on the same surface.

In the above-described artificial photosynthesis module, one in which the water AQ is decomposed to produce oxygen and hydrogen has been described as an example. However, the invention is not limited to this, and methane or the like can be produced.

The raw material fluid to be decomposed can be liquids and gases other than the water AQ, and the raw material fluid to be decomposed is not limited to the water AQ. Additionally, in the electrodes for the artificial photosynthesis module, and the artificial photosynthesis module, the first fluid and the second fluid to be generated are not limited to oxygen and hydrogen, and a liquid or gas can be obtained from the raw material fluid by adjusting the configuration of the electrodes. For example, persulfate can be obtained from sulfuric acid. Hydrogen peroxide can be obtained from water, hypochlorite can be obtained from salt, periodate can be obtained from iodate, and tetravalent cerium can be obtained from trivalent cerium.

The above-described artificial photosynthesis module 10 can be utilized for the artificial photosynthesis device. Also in the artificial photosynthesis device, a case where the raw material fluid is water, the first fluid is oxygen, and the second fluid is hydrogen will be described as an example.

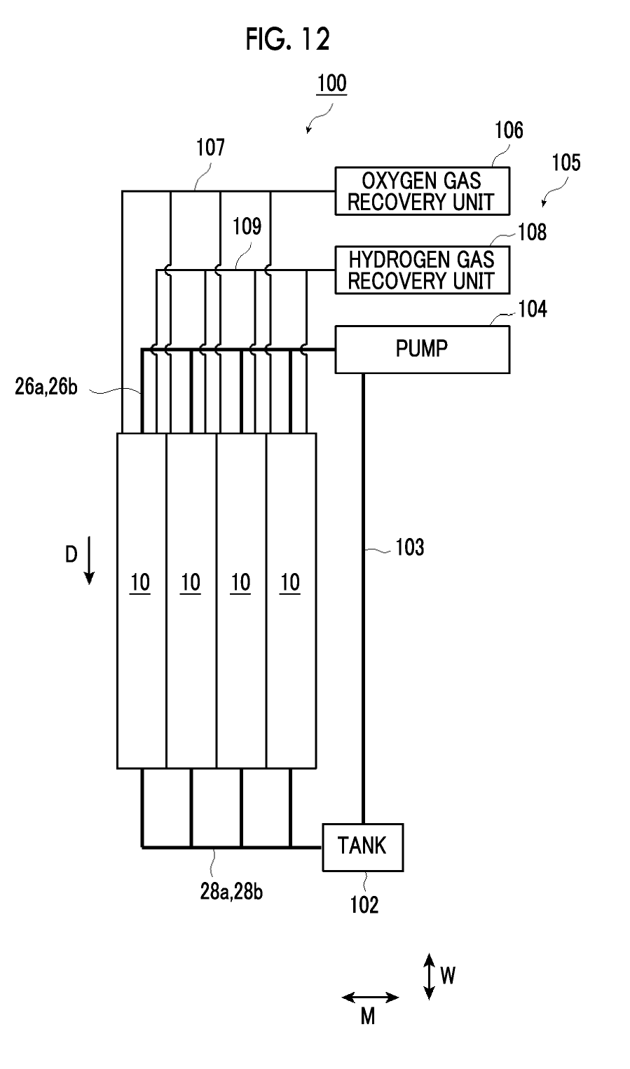

FIG. 12 is a schematic view illustrating a first example of an artificial photosynthesis device of the embodiment of the invention.

An artificial photosynthesis device 100 illustrated in FIG. 12 has an artificial photosynthesis module 10 that decomposes water, which is, for example, a raw material fluid, to obtain fluids, such as gases, a tank 102 that stores water, supply pipes 26a and 26b that are connected to the tank 102 and the artificial photosynthesis module 10 and supply water to the artificial photosynthesis module 10, discharge pipes 28a and 28b that are connected to the tank 102 and the artificial photosynthesis module and recover water from the artificial photosynthesis module, a pump 104 that circulates water between the tank 102 and the artificial photosynthesis module 10 via the supply pipes 26a and 26b and the discharge pipes 28a and 28b, and a gas recovery unit 105 that recovers the obtained fluids, such as the produced gases produced in the artificial photosynthesis module 10.

In the artificial photosynthesis device 100, a plurality of the artificial photosynthesis modules 10 are disposed with the direction D and a direction W being made parallel to each other, and are disposed side by side in a direction M orthogonal to the direction W. Since the configuration of each artificial photosynthesis module 10 is the same as the configuration illustrated in FIG. 1, the detailed description thereof will be omitted. The number of artificial photosynthesis modules 10 is not particularly limited as long as the plurality of artificial photosynthesis modules are provided, and at least two artificial photosynthesis modules may be provided.

The tank 102 stores the water that is the raw material fluid as described above, and for example, stores the water to be supplied to the artificial photosynthesis modules 10, and also stores the raw material fluid, such as the water discharged through the discharge pipes 28a and 28b from the artificial photosynthesis modules 10. The tank 102 is not particularly limited as long as the tank 102 can store the raw material fluid, such as water. The pump 104 is connected to the tank 102 via a pipe 103, and supplies the raw material fluid, such as the water stored in the tank 102 to the artificial photosynthesis modules 10.

The pump 104 also supplies the raw material fluid, such as the water, which is discharged from the artificial photosynthesis modules 10 to the tank 102 and stored, to the artificial photosynthesis modules 10. In this way, the pump 104 circulates the raw material fluid, such as water, between the tank 102 and the artificial photosynthesis modules 10 via the supply pipes 26a and 26b and the discharge pipes 28a and 28b. As long as the pump 104 can circulate the raw material fluid, such as water, between the tank 102 and the artificial photosynthesis modules 10, the pump 104 is not particularly limited, and is appropriately selected on the basis of the amount of the raw material fluid, such as the water to be circulated, the pipe length, or the like.

The gas recovery unit 105 has, for example, an oxygen gas recovery unit 106 that recovers the obtained oxygen gas, such as being created in the artificial photosynthesis modules 10, and a hydrogen gas recovery unit 108 that recovers the obtained hydrogen gas, such as being created in the artificial photosynthesis modules 10.

The oxygen gas recovery unit 106 is connected to the artificial photosynthesis modules 10 via a pipe 107 for oxygen. The configuration of the oxygen gas recovery unit 106 is not particularly limited as long as the oxygen gas recovery unit 106 can recover the obtained gas or liquid fluid, such as the oxygen gas. For example, devices using an adsorption method are available.

The hydrogen gas recovery unit 108 is connected to the artificial photosynthesis modules 10 via a pipe 109 for hydrogen. The configuration of the hydrogen gas recovery unit 108 is not particularly limited as long as the hydrogen gas recovery unit 108 can recover the obtained gas or liquid fluid, such as the hydrogen gas. For example, devices using an adsorption method, a diaphragm process, and the like are available.

In the artificial photosynthesis device 100, the artificial photosynthesis modules 10 may be inclined with respect to the direction W. In this case, a form of the artificial photosynthesis module 10 illustrated in FIG. 7 is obtained. By inclining the artificial photosynthesis modules 10, water is likely to move to the tank 102 side. As a result, the evolution efficiency of the oxygen gas and the hydrogen gas can be made high. Moreover, the oxygen gas produced is likely to move toward the pipe 107 for oxygen, and the hydrogen gas produced is likely to move toward the pipe 109 for hydrogen. As a result, the oxygen gas and the hydrogen gas can be efficiently recovered. The artificial photosynthesis module 10 is not limited to one illustrated in FIG. 1, and the artificial photosynthesis module 60 illustrated in FIG. 8, the artificial photosynthesis module 60 illustrated in FIG. 9, and the artificial photosynthesis module 70 illustrated in FIG. 10 can be used.

In addition, although the hydrogen gas recovery unit 108 and the oxygen gas recovery unit 106 are provided on the pump 104 side, the invention is not limited to this, and the hydrogen gas recovery unit 108 and the oxygen gas recovery unit 106 may be provided on the tank 102 side.

In the artificial photosynthesis device 100, in a case where a certain electric current is supplied to the oxygen evolution electrode 12 and the hydrogen evolution electrode 14 of each artificial photosynthesis module 10 using a potentiostat, oxygen is produced from the oxygen evolution electrode 12, and hydrogen is produced from the hydrogen evolution electrode. Oxygen and hydrogen stagnate as gases at an upper part of the artificial photosynthesis module 10, the oxygen is recovered to the oxygen gas recovery unit 106, and the hydrogen is recovered to the hydrogen gas recovery unit 108.

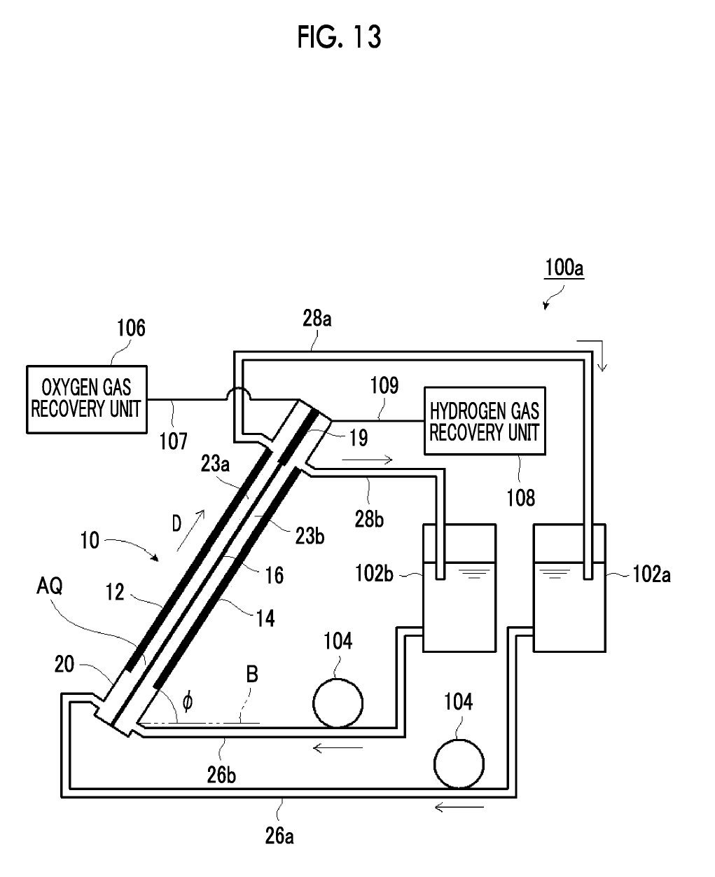

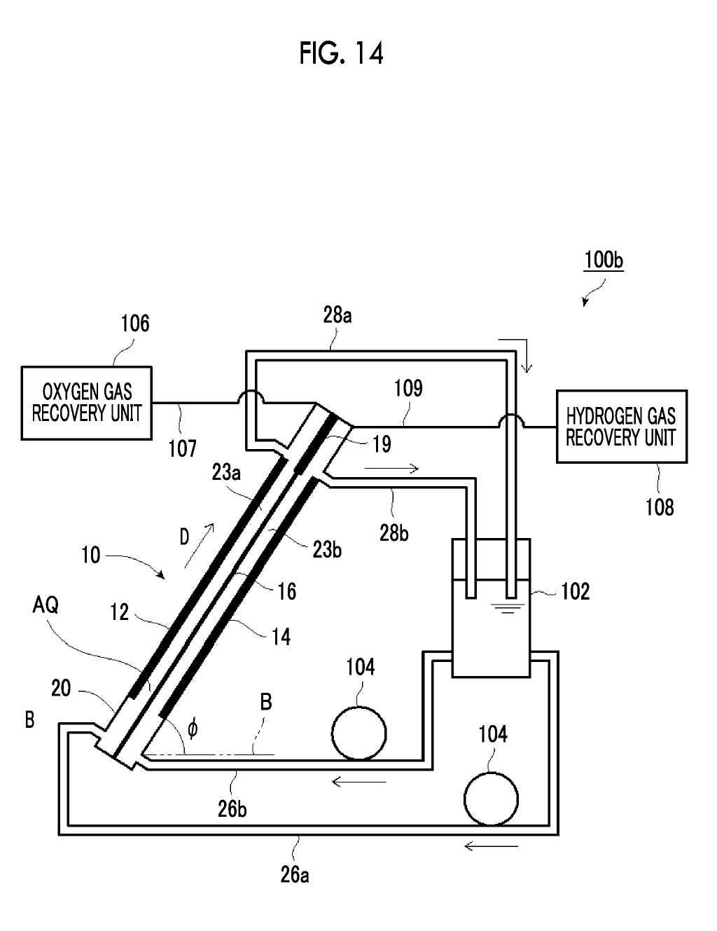

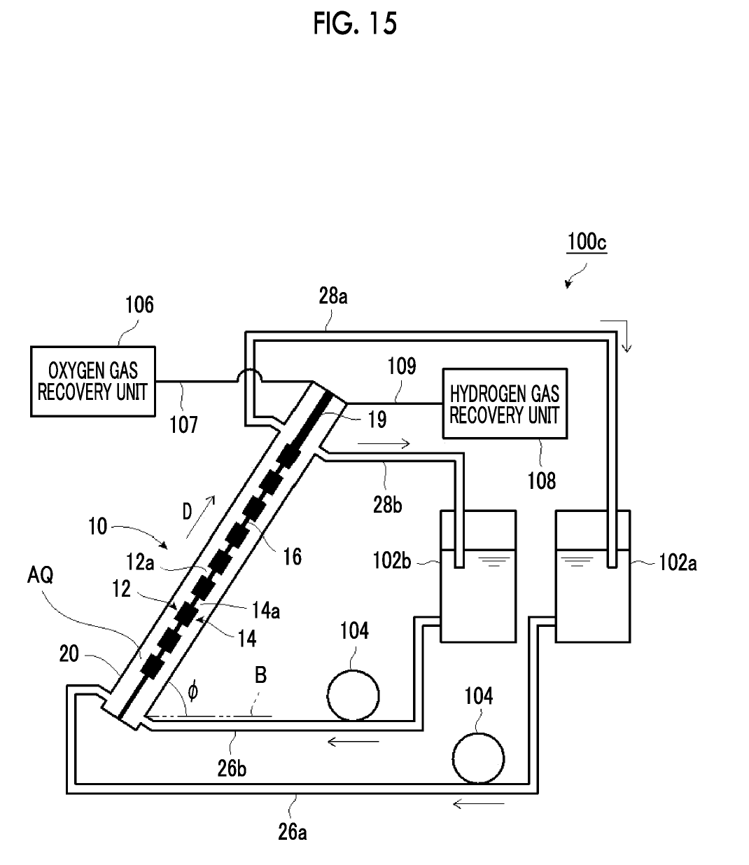

FIG. 13 is a schematic view illustrating a second example of the artificial photosynthesis device of the embodiment of the invention, FIG. 14 is a schematic view illustrating a third example of the artificial photosynthesis device of the embodiment of the invention, and FIG. 15 is a schematic view illustrating a fourth example of the artificial photosynthesis device of the embodiment of the invention. In FIGS. 13 and 15, the same components as those of the artificial photosynthesis module 10 illustrated in FIG. 1 and the artificial photosynthesis device 100 illustrated in FIG. 12 will be designated by the same reference signs, and the detailed description thereof will be omitted.

In an artificial photosynthesis device 100a illustrated in FIG. 13, as compared to the artificial photosynthesis device 100 illustrated in FIG. 12, the first compartment 23a is provided with the pipe 107 for oxygen, and the oxygen gas recovery unit 106 is connected to the pipe 107 for oxygen. The second compartment 23b is provided with the pipe 109 for hydrogen, and the hydrogen gas recovery unit 108 is connected to the pipe 109 for hydrogen. The discharge pipe 28a is connected to a first tank 102a, and the discharge pipe 28b is connected to a second tank 102b.

The first tank 102a and the first compartment 23a are connected to each other by the supply pipe 26a. The supply pipe 26a is provided with a pump 104. The water AQ stored in the first tank 102a is supplied to the first compartment 23a by the pump 104.

The second tank 102b and the second compartment 23b are connected to each other by the supply pipe 26b. The supply pipe 26b is provided with a pump 104. The water AQ stored in the second tank 102b is supplied to the second compartment 23b by the pump 104. In each artificial photosynthesis module 10, the water AQ is supplied in the direction D. Additionally, in the artificial photosynthesis module 10, not the diaphragm 16 but a partition wall 19 is provided on the pipe 107 side for oxygen and the pipe 109 side for hydrogen within the container 20. The partition wall 19 is configured to not allow gases to permeate therethrough, and mixing of hydrogen and oxygen that are produced within the container 20 is suppressed. In addition, in the artificial photosynthesis device 100a, the artificial photosynthesis module 10 is disposed to be inclined at 45° with respect to the horizontal plane B.

In the artificial photosynthesis device 100a, in a case where a certain electric current is supplied to the oxygen evolution electrode 12 and the hydrogen evolution electrode 14 of the artificial photosynthesis module 10 using the potentiostat, oxygen is produced from the oxygen evolution electrode 12, and hydrogen is produced from the hydrogen evolution electrode. The oxygen and the hydrogen stagnate as gases at the upper part of the artificial photosynthesis module 10, mixing of the hydrogen and the oxygen is suppressed by the partition wall 19, the oxygen is recovered to the oxygen gas recovery unit 106, and the hydrogen is recovered to the hydrogen gas recovery unit 108.

In an artificial photosynthesis device 100b illustrated in FIG. 14, as compared to the artificial photosynthesis device 100 illustrated in FIG. 12, the first compartment 23a is provided with the pipe 107 for oxygen, and the oxygen gas recovery unit 106 is connected to the pipe 107 for oxygen. The second compartment 23b is provided with the pipe 109 for hydrogen, and the hydrogen gas recovery unit 108 is connected to the pipe 109 for hydrogen. The discharge pipe 28a and the discharge pipe 28b are connected to the tank 102. The number of tanks 102 of the artificial photosynthesis device 100b illustrated in FIG. 14 is one.

The tank 102 and the first compartment 23a are connected to each other by the supply pipe 26a. The supply pipe 26a is provided with the pump 104. The water AQ stored in the tank 102 is supplied to the first compartment 23a by the pump 104. The tank 102 and the second compartment 23b are connected to each other by the supply pipe 26b. The supply pipe 26b is provided with the pump 104.

The water AQ stored in the tank 102 is supplied to the second compartment 23b by the pump 104. The number of tanks 102 is one, and the water AQ from the first compartment 23a and the water AQ from the second compartment 23b are mixed with each other and stored in the tank 102. Accordingly, pH of the water AQ to be supplied by the pump 104 approaches pH of the water AQ to be supplied first. A deviation is caused in the difference of pH of the water AQ in first compartment 23a and the second compartment 23b as time passes, the deviation of pH of the water AQ causes an increase in electrolysis voltage, that is, a decrease in conversion efficiency inevitably occurs. However, by disposing one tank 102, the effects that the deviation of pH of the water AQ is suppressed and the increase in electrolysis voltage with the passage of time is suppressed can be obtained.

In the artificial photosynthesis module 10, the water AQ is supplied in the direction D. Additionally, in the artificial photosynthesis module 10, not the diaphragm 16 but the partition wall 19 is provided on the pipe 107 side for oxygen and the pipe 109 side for hydrogen within the container 20. The partition wall 19 is configured to not allow gases to permeate therethrough, and mixing of hydrogen and oxygen that are produced within the container 20 is suppressed. In addition, in the artificial photosynthesis device 100b, the artificial photosynthesis module 10 is disposed to be inclined at 45° with respect to the horizontal plane B.

In the artificial photosynthesis device 100b, in a case where a certain electric current is supplied to the oxygen evolution electrode 12 and the hydrogen evolution electrode 14 of the artificial photosynthesis module 10 using the potentiostat, oxygen is produced from the oxygen evolution electrode 12, and hydrogen is produced from the hydrogen evolution electrode. The oxygen and the hydrogen stagnate as gases at the upper part of the artificial photosynthesis module 10, mixing of the hydrogen and the oxygen is suppressed by the partition wall 19, the oxygen is recovered to the oxygen gas recovery unit 106, and the hydrogen is recovered to the hydrogen gas recovery unit 108.

In an artificial photosynthesis device 100c illustrated in FIG. 15, as compared to the artificial photosynthesis device 100 illustrated in FIG. 12, the first compartment 23a is provided with the pipe 107 for oxygen, and the oxygen gas recovery unit 106 is connected to the pipe 107 for oxygen. The second compartment 23b is provided with the pipe 109 for hydrogen, and the hydrogen gas recovery unit 108 is connected to the pipe 109 for hydrogen. The discharge pipe 28a is connected to the first tank 102a, and the discharge pipe 28b is connected to the second tank 102b.

The first tank 102a and the first compartment 23a are connected to each other by the supply pipe 26a. The supply pipe 26a is provided with a pump 104. The water AQ stored in the first tank 102a is supplied to the first compartment 23a by the pump 104.

The second tank 102b and the second compartment 23b are connected to each other by the supply pipe 26b. The supply pipe 26b is provided with a pump 104. The water AQ stored in the second tank 102b is supplied to the second compartment 23b by the pump 104. In the artificial photosynthesis module 10, the water AQ is supplied in the direction D. Additionally, in the artificial photosynthesis module 10, not the diaphragm 16 but the partition wall 19 is provided on the pipe 107 side for oxygen and the pipe 109 side for hydrogen within the container 20. The partition wall 19 is configured to not allow gases to permeate therethrough, and mixing of hydrogen and oxygen that are produced within the container 20 is suppressed. In addition, in the artificial photosynthesis device 100c, the artificial photosynthesis module 10 is disposed to be inclined at 45° with respect to the horizontal plane B.

In the artificial photosynthesis device 100c, in a case where a certain electric current is supplied to the oxygen evolution electrode 12 and the hydrogen evolution electrode 14 of the artificial photosynthesis module 10 using the potentiostat, oxygen is produced from the oxygen evolution electrode 12, and hydrogen is produced from the hydrogen evolution electrode. The oxygen and the hydrogen stagnate as gases at the upper part of the artificial photosynthesis module 10, mixing of the hydrogen and the oxygen is suppressed by the partition wall 19, the oxygen is recovered to the oxygen gas recovery unit 106, and the hydrogen is recovered to the hydrogen gas recovery unit 108.

Also in the artificial photosynthesis device 100c, only one tank 102 may be provided as in the above-described artificial photosynthesis device 100b. By providing one tank 102 as described above, the effects that the deviation of pH of the recovered water AQ is suppressed and an increase in electrolysis voltage with the passage of time is suppressed can be obtained.

The oxygen evolution electrode 12 is provided with through-holes 12a, and the hydrogen evolution electrode 14 is provided with through-holes 14a. The diaphragm 16 is disposed and sandwiched between the hydrogen evolution electrode 14 and the oxygen evolution electrode 12.

By virtue of the through-holes 12a and 14a, the produced bubbles escape to an electrode on the side opposite to each electrode, and flow through the back side of the electrode. Accordingly, a situation in which the bubbles are sandwiched between the diaphragm 16 and each electrode, hinder the flow of the water AQ, and the flow of ions through the diaphragm 16, and increase the electrolysis voltage can be suppressed. Additionally, since the sandwiching of the bubbles is suppressed, the electrode interval can be further narrowed. Therefore, the electrolysis voltage can be lowered, that is, the conversion efficiency can be raised. Additionally, since solar light is transmitted through the hydrogen evolution electrode from the through-holes of the oxygen evolution electrode, it is unnecessary for the oxygen evolution electrode to be transparent, it is unnecessary to use high-resistance transparent electrode films, such as an indium tin oxide (ITO) film having high electrical resistance, and the electrolysis voltage can be further lowered.

In the above-described artificial photosynthesis devices 100a, 100b, and 100c, the inclination angles thereof are set to 45°. However, the invention is not particularly limited to this, and solar light can be efficiently utilized by inclining the module 10 to the incidence direction of the solar light according to the latitude. Additionally, in the above-described artificial photosynthesis devices 100, 100a, 100b, and 100c, the concentration of the hydrogen, which has permeated through the diaphragm 16 and has moved from the second compartment 23b to the first compartment 23a, is defined as hydrogen permeation concentration. Since the hydrogen that has moved from the second compartment 23b to the first compartment 23a is regarded as impurities with respect to oxygen, the hydrogen permeation concentration is ideally 0%, but an upper limit thereof is 4% or less. In a case where the evolution efficiency of oxygen is taken into consideration in order to raise oxygen purity in a post process, it is desirable that the hydrogen permeation concentration is suppressed to be 2% or less in practice. However, in a case where the hydrogen permeation concentration is 2% or less, a decrease in the evolution efficiency of oxygen is suppressed.

Additionally, the concentration of the oxygen, which has permeated through the diaphragm 16 and has moved from the first compartment 23a to the second compartment 23b, is defined as oxygen permeation concentration. Since the oxygen that has moved from the first compartment 23a to the second compartment 23b is regarded as impurities with respect to hydrogen, the oxygen permeation concentration is ideally 0%, but an upper limit thereof is 4% or less. In a case where the evolution efficiency of hydrogen is taken into consideration in order to raise hydrogen purity in a post process, it is desirable that the oxygen permeation concentration is suppressed to be 2% or less in practice. However, in a case where the oxygen permeation concentration is 2% or less, a decrease in the evolution efficiency of hydrogen is suppressed. From such a fact, as the mixing of oxygen and hydrogen is smaller, the energy for obtaining high-purity oxygen and hydrogen can be reduced, and the evolution efficiency of oxygen and hydrogen can be enhanced.

The invention is basically configured as described above. Although the artificial photosynthesis module and the artificial photosynthesis device of the invention have been described above in detail, it is natural that the invention is not limited to the above-described embodiments, and various improvements or modifications may be made without departing from the scope of the invention.

### Example 1

Hereinafter, the features of the invention will be more specifically described with reference to examples. Materials, reagents, amounts used, substance amounts, ratios, treatment contents, treatment procedures, and the like that are shown in the following examples can be appropriately changed, unless departing from the spirit of the invention. Therefore, the scope of the invention should not be restrictively interpreted by the specific examples shown below.

In a first example, in order to confirm the effects of the invention, artificial photosynthesis modules of Example 1, Comparative Examples 1, and Reference Example 1 shown below were made.

In the first example, a control was made by the potentiostat such that a current value equivalent to the conversion efficiency of 10% became constant while supplying the electrolytic aqueous solution to the artificial photosynthesis modules of Example 1, Comparative Examples 1, and Reference Example 1, changes in electrolysis voltage were measured for 10 minutes from the start of the control, and electrolysis voltages after 10 minutes were determined. The results are shown in Table 1. HZ-7000 made by HOKUTO DENKO CORP was used for the potentiostat.

In addition, the “electrolysis voltages after 10 minutes” are parameters for evaluating the “energy conversion efficiency”. As the electrolysis voltages for applying a certain amount of electrolytic current equivalent to the above-described conversion efficiency of 10%, the energy conversion efficiency is better.

Additionally, the hydrogen permeation concentration and the oxygen permeation concentration were measured regarding the artificial photosynthesis modules of Example 1, Comparative Example 1, and Reference Example 1. In addition, the hydrogen permeation concentration and the oxygen permeation concentration were measured as follows.

[Method of Measuring Hydrogen Permeation Concentration]

First, a gas recovery port of a compartment on an oxygen evolution side of an artificial photosynthesis module and a gas chromatographic apparatus (MICRO GC 490 made by AGILENT TECHNOLOGIES (product name)) were connected to each other, and the air within the artificial photosynthesis module was substituted with nitrogen. Hydrogen and oxygen were produced by applying an electric current to the artificial photosynthesis module such that the current value equivalent to the conversion efficiency of 10% becomes constant after the oxygen and the hydrogen other than the nitrogen were confirmed to be equal to or lower than a measurement limit by the gas chromatographic apparatus. The oxygen produced from an oxygen evolution electrode from a first compartment on the oxygen evolution side, and the hydrogen that has passed through a diaphragm from a second compartment on a hydrogen evolution side and has permeated through the first compartment on the oxygen evolution side, are detected by the gas chromatographic apparatus. The concentration of the permeated hydrogen in a case where the concentration obtained by adding the amount of the hydrogen passed through as described above and the amount of the oxygen originally produced was 100% was taken as the hydrogen permeation concentration.

[Method of Measuring Oxygen Permeation Concentration]

First, a gas recovery port of a compartment on a hydrogen evolution side of the artificial photosynthesis module and the gas chromatographic apparatus (MICRO GC 490 made by AGILENT TECHNOLOGIES (product name)) were connected to each other, and the air within the artificial photosynthesis module was substituted with nitrogen. Hydrogen and oxygen were produced by applying an electric current to the artificial photosynthesis module such that the current value equivalent to the conversion efficiency of 10% becomes constant after the oxygen and the hydrogen other than the nitrogen were confirmed to be equal to or lower than the measurement limit by the gas chromatographic apparatus. The hydrogen produced from the hydrogen evolution electrode from the second compartment on the hydrogen evolution side, and the oxygen that has passed through the diaphragm from the first compartment on the oxygen evolution side and has permeated through the second compartment on the hydrogen evolution side, are detected by the gas chromatographic apparatus. The concentration of the permeated oxygen in a case where the concentration obtained by adding the amount of the oxygen passed through as described above and the amount of the hydrogen originally produced was 100% was taken as the oxygen permeation concentration.

Additionally, the light transmittances of diaphragms using for Example 1 and Comparative Example 1 were measured. Reference Example 1 uses no diaphragm. The light transmittances were measured as follows.

[Measurement of Light Transmittance]

SH7000 made by NIPPON DENSHOKU, INC. that is generally used was used as a transmittance measuring device for the measurement of the light transmittances of the diaphragms. In the measurement of the light transmittances of the diaphragms, a light transmittance was measured with a diaphragm being set in the transmittance measuring device in a state where the diaphragm was immersed in pure water after the diaphragm was immersed in the pure water for one minute. In the transmittance measuring device, the light transmittances were calculated as the amounts of light transmitted, which were obtained by integrating all the light transmitted in the wavelength range having a wavelength of 380 nm to 780 nm with an integrating sphere.

[Measurement and Determination of Hydrophilicity and Hydrophobicity]

A 2θ method used for measurement of angles of contact was used for measurement of the hydrophilicity and the hydrophobicity. First, five microliters of droplets that are ultra-pure water were added dropwise onto the surfaces of a diaphragm, an image of the droplets and the diaphragm was captured by a microscope (VHS-5000 made by KEYENCE CORPORATION) from a side face, then lines were drawn from points of contact between the droplets and the diaphragm to droplet peaks, and values obtained by doubling the angles between the lines and the surface of the diaphragm were used as the angles of contact. A case where the droplets permeated through the diaphragm due to the hydrophilicity and the angles of contact could not be measured was determined as the hydrophilicity. A case where the droplets did not permeate through the diaphragm and remained on the diaphragm in a droplet state was determined as the hydrophobicity. In addition, all the angles of contact in a case where the droplets remained were 90° or more.

In addition, the catalog values of a diaphragm to be used were used for the thickness and average hole diameter of the diaphragm.

Hereinafter, the artificial photosynthesis modules of Example 1, Comparative Example 1, and Reference Example 1 will be described. In addition, in all of the artificial photosynthesis modules of Example 1, Comparative Example 1, and Reference Example 1, a hydrogen evolution electrode and an oxygen evolution electrode are disposed within a container in which an electrolytic aqueous solution inlet part and an electrolytic aqueous solution outlet part are provided. A diaphragm was disposed between the hydrogen evolution electrode and the oxygen evolution electrode. The distance, that is, the interval, between a surface of the hydrogen evolution electrode and a surface of the oxygen evolution electrode was 4 mm. The container was disposed to be inclined at 45°.

Regarding a method of supplying the electrolytic aqueous solution, the electrolytic aqueous solution was made to flow parallel to the surface of the hydrogen evolution electrode and the surface of the oxygen evolution electrode and a honeycomb straightening plate was provided such that the flow of the electrolytic aqueous solution became laminar flows on the surface of the oxygen evolution electrode and on the surface of the hydrogen evolution electrode. An electrolytic solution with 0.5 M of Na₂SO₄+Pi (phosphate buffer) and pH 6.5 was used for the electrolytic aqueous solution.

### Example 1

In an artificial photosynthesis module of Example 1, a hydrogen evolution electrode and an oxygen evolution electrode are flat plates, and are referred to as solid electrodes. Electrodes (Exceload EA): JAPAN CARLIT CO., LTD.) obtained by performing platinum plating treatment of a thickness of 1 μm on the surface of a flat base material made of titanium and having electrode dimensions of 100 mm×100 mm were used for the hydrogen evolution electrode and the oxygen evolution electrode.

In Example 1, a PTFE membrane (ADVANTEC H100A (product name) (a membrane thickness of 35 μm (0.035 mm) and an average hole diameter of 1.0 μm)) was used for a diaphragm. The diaphragm of Example 1 is hydrophilic, and the membrane quality is a membrane.

In addition, in Example 1, the electrolytic aqueous solution was made to flow at a flow rate of 1.0 liter/min in the direction D illustrated in FIG. 1.

### Comparative Example 1

An artificial photosynthesis module of Comparative Example 1 had the same configuration as Example 1 except that a Teflon (registered trademark) fiber-reinforced Nafion (registered trademark) membrane (sigma-aldrich Nafion (registered trademark) 324 (product name) (a membrane thickness of 152 μm (0.152 mm), an average hole diameter of less than 0.001 μm, and a fiber-reinforced mesh)) was used for a diaphragm. The diaphragm of Comparative Example 1 is hydrophilic, and the membrane quality is a membrane. For this reason, the detailed description thereof will be omitted. A hydrogen evolution electrode and an oxygen evolution electrode of Comparative Example 1 have a configuration referred to as a solid electrode.

### Reference Example 1

An artificial photosynthesis module of Reference Example 1 had the same configuration as Example 1 except that no diaphragm is used. For this reason, the detailed description thereof will be omitted. A hydrogen evolution electrode and an oxygen evolution electrode of Reference Example 1 have a configuration referred to as a solid electrode. In Reference Example 1, since there was no diaphragm and produced oxygen and hydrogen were mixed with each other, the hydrogen permeation concentration and the oxygen permeation concentration were not measured. “Mixed” was written in the columns of “Hydrogen permeation concentration” and “Oxygen permeation concentration of the following Table 1.

TABLE 1

| | Diaphragm | | | | | | | |
|---|---|---|---|---|---|---|---|---|
| | | Average | | | | Electrolysis | Hydrogen | Oxygen |
| | | hole | | | Light | voltage (V) | permeation | permeation |
| | Thickness | diameter | Membrane | Hydrophilicty/ | transmittance | after 10 | concentration | concentration |
| | (mm) | (μm) | Quality | Hydrophobicity | (%) | minutes | (%) | (%) |
| Example 1 | 0.035 | 1.0 | Membrane | Hydrophilic | 92.2 | 2.69 | 0.92 | 1.17 |
| Comparative | 0.152 | <0.001 | Membrane | Hydrophilic | 32.8 | 2.96 | 0.45 | 0.49 |
| Example 1 | | | | | | | | |
| Reference | — | — | — | — | — | 2.64 | Mixed | Mixed |
| Example | | | | | | | | |

As shown in Table 1, Example 1 had smaller electrolysis voltages and excellent energy conversion efficiency as compared to Comparative Example 1. In addition, in the reference example, the hydrogen and oxygen produced may be mixed with each other. Thus, it is necessary to separate the oxygen and the hydrogen, and the conversion efficiency is poor. Example 1 had almost the same electrolysis voltage as that of Reference Example 1.

### Example 2

In a second example, artificial photosynthesis modules of Examples 2 to 5 and Comparative Examples 2 and 4 shown below were made. The artificial photosynthesis device having the configuration illustrated in FIG. 13 was configured using the respective artificial photosynthesis modules.

In the second example, electrolysis voltages, hydrogen permeation concentrations, and oxygen permeation concentrations after 10 minutes were measured regarding the artificial photosynthesis modules of Examples 2 to 5 and Comparative Examples 2 and 4. The results are illustrated in the following Table 2. In addition, since the measurement of the electrolysis voltage, the hydrogen permeation concentrations, and the oxygen permeation concentrations after 10 minutes are the same as those of the above-described first example except that 1 M of an Na₂SO₄ electrolytic aqueous solution is used for the electrolytic solution, the electrolytic aqueous solution is made to flow in the direction D illustrated in FIG. 13, and the flow rate of the electrolytic aqueous solution is 4.2 cm/sec, the detailed description thereof will be omitted.

Light transmittances, hydrophilicities and hydrophobicities, diaphragm thicknesses, and diaphragm average hole diameters of Examples 2 to 5 and Comparative Examples 2 to 4 are shown in the following Table 2. In addition, since measurement of the light transmittances, measurement and determination of the hydrophilicities and hydrophobicities, the diaphragm thicknesses, and the diaphragm average hole diameters and the same as those of the above-described first example, the detailed description thereof will be omitted.

Hereinafter, Examples 2 to 5 and Comparative Examples 2 to 4 will be described.

### Example 2

Example 2 had the same configuration as that of Example 1 except that a PTFE membrane (MILLIPORE OMNIPORE 1.0 (product name) (a membrane thickness of 85 (0.085 mm) and an average hole diameter of 1.0 μm)) was used for a diaphragm, as compared to the above-described Example 1. The diaphragm of Example 2 is hydrophilic, and the membrane quality is a membrane.

### Example 3

Example 3 had the same configuration as that of Example 1 except that a PTFE membrane (MILLIPORE OMNIPORE 10 (product name) (a membrane thickness of 85 μm (0.085 mm) and an average hole diameter of 10.0μm)) was used for a diaphragm, as compared to the above-described Example 1. The diaphragm of Example 3 is hydrophilic, and the membrane quality is a membrane.

### Example 4

Example 4 had the same configuration as that of Example 1 except that a PTFE membrane (MILLIPORE OMNIPORE 0.1 (product name) (a membrane thickness of 30 μm (0.030 mm) and an average hole diameter of 0.1 μm)) was used for a diaphragm, as compared to the above-described Example 1. The diaphragm of Example 4 is hydrophilic, and the membrane quality is a membrane.

### Example 5

Example 5 has the same configuration as that of Example 1 except that a PTFE membrane (FP-100-100 (product name) (a membrane thickness of 100 μm (0.100 mm) and an average hole diameter of 3.2 μm) of TOBUTSU TECHNO Corporation) was used for a diaphragm, as compared to the above-described Example 1. The diaphragm of Example 5 is subjected to hydrophilic treatment from its hydrophobicity, and the membrane quality is porous. As the hydrophilic treatment, the method shown in WO2014/021167 was used.

### Comparative Example 2

Comparative Example 2 had the same configuration as that of Example 1 except that a PTFE membrane (MF-250BN (product name) (a membrane thickness of 170 μm (0.170 mm) and an average hole diameter of 2.5 μm) of YUASA CORP.) was used for a diaphragm, as compared to the above-described Example 1. The diaphragm of Comparative Example 2 is subjected to hydrophilic treatment from its hydrophobicity, and the membrane quality is nonwoven paper. As the hydrophilic treatment, the method shown in WO2014/021167 was used.

### Comparative Example 3

Comparative Example 3 had the same configuration as that of Example 1 except that a PET membrane (PET51-HD (product name) (a membrane thickness of 60 μm (0.060 mm) and an average hole diameter of 50.0 μm) of Sefar AG) was used for a diaphragm, as compared to the above-described Example 1. The diaphragm of Comparative Example 3 is subjected to hydrophilic treatment from its hydrophobicity, and the membrane quality is a mesh. As the hydrophilic treatment, the method shown in WO2014/021167 was used. “>4.0” of the column of “Oxygen permeation concentration” shown in the following Table 2 shows that oxygen permeation concentration is more than 4.0%.

### Comparative Example 4

Comparative Example 4 had the same configuration as that of Example 1 except that a cellulose film (a membrane thickness of 22 μm (0.022 mm) and an average hole diameter of less than 0.1 μm) of Futamura Chemical Co., Ltd. was used for a diaphragm, as compared to the above-described Example 1. The diaphragm of Comparative Example 4 is hydrophilic, and the membrane quality is a membrane.

TABLE 2

| | Diaphragm | | | | | | | |
|---|---|---|---|---|---|---|---|---|
| | | Average | | | | Electrolysis | Hydrogen | Oxygen |
| | | hole | | | Light | voltage (V) | permeation | permeation |
| | Thickness | diameter | Membrane | Hydrophilicty/ | transmittance | after 10 | concentration | concentration |
| | (mm) | (μm) | Quality | Hydrophobicity | (%) | minutes | (%) | (%) |
| Example 2 | 0.085 | 1.0 | Membrane | Hydrophilic | 90.7 | 2.64 | 1.02 | 0.89 |
| Example 3 | 0.085 | 10.0 | Membrane | Hydrophilic | 92.4 | 2.71 | 1.54 | 0.96 |
| Example 4 | 0.030 | 0.1 | Membrane | Hydrophilic | 90.7 | 2.67 | 0.93 | 0.77 |
| Example 5 | 0.100 | 3.2 | Porous | Hydrophobic | 90.9 | 2.90 | 0.35 | 0.54 |
| | | | | (Hydrophilic | | | | |
| | | | | treatment) | | | | |
| Comparative | 0.170 | 2.5 | Nonwoven | Hydrophobic | 56.3 | 2.97 | 0.49 | 0.11 |
| Example 2 | | | paper | (Hydrophilic | | | | |
| | | | | treatment) | | | | |
| Comparative | 0.060 | 50.0 | Mesh | Hydrophobic | 80.7 | 2.71 | 3.29 | >4.0 |
| Example 3 | | | | (Hydrophilic | | | | |
| | | | | treatment) | | | | |
| Comparative | 0.022 | <0.1 | Membrane | Hydrophilic | 92.3 | 3.25 | 0.26 | 0.12 |
| Example 4 | | | | | | | | |

As shown in Table 2, Examples 2 to 4 have the same configuration except that thicknesses and average hole diameters are different. It was confirmed from Examples 2 to 4 that practical electrolysis voltages were obtained at an average hole diameter of at least 0.1 μm to 10.0 μm and a membrane thickness of 35 μm to 85 μm or less. Additionally, regarding Examples 2 to 4, it was confirmed that the oxygen permeation concentration of the oxygen and the hydrogen permeation concentration of the hydrogen that have passed through a diaphragm and escaped to opposite sides, are 2% or less in practice for raising purity in a post process.

In Example 5, the hydrophilic treatment was performed. However, the light transmittance could be 90% or more, the electrolysis voltage could be 3.0 V or less, and the hydrogen permeation rate could be 2% or less.

In Comparative Example 2, the Light transmittance is low, the electrolysis voltage after 10 minutes is high, and the conversion efficiency is poor.

In Comparative Example 3, the average hole diameter is large, the hydrogen permeation concentration is as high as 3.29%, and the oxygen permeation concentration is as high as more than 4.0%, which were unsuitable for practical performance. In Comparative Example 4, the electrolysis voltage after 10 minutes is high, and the conversion efficiency is poor.

### Example 3

In a third Example, the effects of a separation circulation system in which electrolytic solutions are separately circulated, and a mixed circulation system in which an electrolytic solution is collectively recovered in one tank and is circulated was investigated.

The artificial photosynthesis device having the configuration illustrated in FIG. 14 was used in Example 7, and the artificial photosynthesis device having the configuration illustrated in FIG. 13 was used in Example 6.

Regarding Examples 6 and 7, the electrolysis voltages were measured after 10 minutes, after 20 minutes, after 60 minutes, and after 120 minutes. The results are shown in the following Table 3.

Since the method of measuring the electrolysis voltages are the same as that of the above-described first example except that 1 M of an Na₂SO₄ electrolytic aqueous solution is used for the electrolytic solution, the electrolytic aqueous solution is made to flow in the direction D illustrated in FIGS. 13 and 14, and the flow rate of the electrolytic aqueous solution is 4.2 cm/sec, the detailed description thereof will be omitted.

Hereinafter, Examples 6 and 7 will be described.

### Example 6

Example 6 had the same configuration as that of Example 1 except that electrolytic solutions were separately circulated through an oxygen evolution electrode and a hydrogen evolution electrode, as compared to Example 1.

### Example 7

Example 7 has the same configuration as that of Example 1 except that an electrolytic solution was collectively recovered in one tank and circulated through an oxygen evolution electrode and a hydrogen evolution electrode, as compared to Example 1.

TABLE 3

| | Diaphragm | | | | | | | | |
|---|---|---|---|---|---|---|---|---|---|
| | | Average | | | | | | | |
| | | hole | | | Light | Electrolysis voltage (V) | | | |
| | Thickness | diameter | Membrane | Hydrophilicty/ | transmittance | After | After | After | After |
| | (mm) | (μm) | Quality | Hydrophobicity | (%) | 10 minutes | 20 minutes | 60 minutes | 120 minutes |
| Example 6 | 0.035 | 1.0 | Membrane | Hydrophilic | 92.2 | 2.64 | 2.68 | 2.77 | 2.99 |
| Example 7 | 0.035 | 1.0 | Membrane | Hydrophilic | 92.2 | 2.65 | 2.69 | 2.74 | 2.78 |

As shown in Table 3, in the separation circulation system of Example 6 and the mixed circulation system of Example 7, the electrolysis voltage is kept low in the mixed circulation system of Example 7, that is, the conversion efficiency is kept high in Example 7, in a case where 60 minutes or more has passed. In a case where a diaphragm is used, the oxygen evolution electrode and the hydrogen evolution electrode are partitioned by the diaphragm. Therefore, the deviation of pH of the electrolytic aqueous solution of each compartment occurs as time passes. Accordingly, an increase in electrolysis voltage, that is, a decrease in conversion efficiency, occurs inevitably. However, in the mixed circulation system of Example 7, the electrolytic aqueous solution recovered in one tank is circulated and utilized. Therefore, the effect of suppressing the deviation of pH of the electrolytic aqueous solution within the tank and suppressing an increase in electrolysis voltage with the passage of time is excellent.

### Example 4

In a fourth example, effects caused by differences in configuration between an oxygen evolution electrode and a hydrogen evolution electrode were investigated.

Electrolysis voltages after 10 minutes were measured regarding Example 8 having a flat-plate electrode configuration referred to as a solid electrode, and Example 9 having a mesh electrode configuration. The results are shown in the following Table 4.

Since the method of measuring the electrolysis voltages are the same as that of the above-described first example except that 1 M of an Na₂SO₄ electrolytic aqueous solution is used for the electrolytic solution, the electrolytic aqueous solution is made to flow in the direction D illustrated in FIG. 15, and the flow rate of the electrolytic aqueous solution is 4.2 cm/sec, the detailed description thereof will be omitted.

Hereinafter, Examples 8 and 9 will be described.

### Example 8

Example 8 has the same configuration as that of Example 1. The artificial photosynthesis device having the configuration illustrated in FIG. 13 was used for Example 8.

### Example 9

Example 9 had the same configuration as Example 1 except that an oxygen evolution electrode and a hydrogen evolution electrode had the mesh electrode configuration in which platinum wires having a diameter of 0.08 mm were knitted in 80 pieces/inch, as compared to Example 1. The artificial photosynthesis device having the configuration illustrated in FIG. 15 was used for Example 9.

TABLE 4

| | Diaphragm | | | | Light | Electrolysis |
|---|---|---|---|---|---|---|
| | Thickness | Average hole | Membrane | Hydrophilicty/ | transmittance | voltage (V) |
| | (mm) | diameter (μm) | Quality | Hydrophobicity | (%) | after 10 minutes |
| Example 8 | 0.035 | 1.0 | Membrane | Hydrophilic | 92.2 | 2.64 |
| Example 9 | 0.035 | 1.0 | Membrane | Hydrophilic | 92.2 | 2.73 |

As illustrated in Table 4, in Example 9 having the mesh electrode configuration, the electrolysis voltage equal to that of Example 8 could be maintained, and high conversion efficiency could be maintained.

In Example 9, by virtue of the through-holes of the oxygen evolution electrode and the hydrogen evolution electrode, the produced bubbles escape to an electrode on the side opposite to each electrode, and flow through the back of the electrode. Accordingly, a situation in which the bubbles are sandwiched between the diaphragm and each electrode, hinders the flow of the electrolytic solution, and the flow of ions through the diaphragm, and increases the electrolysis voltage is suppressed. Additionally, since the sandwiching of the bubbles is suppressed, the electrode interval can be further narrowed. Therefore, the electrolysis voltage can be lowered, that is, the conversion efficiency can be raised. Additionally, since solar light is transmitted through the hydrogen evolution electrode from the through-holes of the oxygen evolution electrode, it is unnecessary for the oxygen evolution electrode to be transparent, it is unnecessary to use high-resistance transparent electrode films, such as an indium tin oxide (ITO) film having high electrical resistance, and the electrolysis voltage can be further lowered.

### EXPLANATION OF REFERENCES

10, 60, 70: artificial photosynthesis module
12: oxygen evolution electrode
12a, 14a: through-hole
14: hydrogen evolution electrode
16: diaphragm
16a, 24a, 34a, 40a, 42a, 44a: surface
16b: back face
17: through-hole
18: conducting wire
20: container
22b: bottom face
22c: first wall face
22d: second wall face
23a: first compartment
23b: second compartment
24: transparent member
26a, 26b: supply pipe
28a, 28b: discharge pipe
30: first substrate
32: first conductive layer
34: first photocatalyst layer
36: first co-catalyst
37: co-catalyst particles
40: second substrate
42: second conductive layer
44: second photocatalyst layer
46: second co-catalyst
47: co-catalyst particles
50, 51, 52: bubbles
62, 64: projecting part
62a, 64a: protrusion
62b, 64b: recess
62c, 62d, 64c, 64d: surface
62e, 64e: maximum projecting end
72a: first electrode part
72b: first gap
72c, 74c: base part
74a: second electrode part
74b: second gap
80: Nafion (registered trademark) membrane having thickness of 0.1 mm
82: porous cellulose membrane
84: hydrophilic PTFE (polyethylene terephthalate) membrane having hole diameter of 0.1 μm
86: hydrophilic PTFE (polyethylene terephthalate) membrane having hole diameter of 1.0 μm
88: hydrophilic PTFE (polyethylene terephthalate) membrane having hole diameter of 10 μm
100, 100a, 100b, 100c: artificial photosynthesis device
102, 102a, 102b: tank
103: pipe
104: pump
105: gas recovery unit
106: oxygen gas recovery unit
107: pipe for oxygen
108: hydrogen gas recovery unit
109: pipe for hydrogen
AQ: water
B: horizontal plane
D: direction
Db: average bubble diameter
Dh: hole diameter
Di: traveling direction
Dp: hole diameter
F_{A}: direction
L: light
Lq: liquid
W: direction
d: thickness
h: height
ϕ: angle

What is claimed is:

1. An artificial photosynthesis module comprising:
a first electrode that decomposes a raw material fluid with light to obtain a first fluid;
a second electrode that decomposes the raw material fluid with the light to obtain a second fluid; and
a diaphragm disposed between the first electrode and the second electrode,
wherein the diaphragm is formed of a membrane having through-holes, is immersed in pure water having a temperature of 25° C. for one minute, and has a light transmittance of 60% or more in a wavelength range of 380 nm to 780 nm in a state where the diaphragm is immersed in the pure water, and
wherein an average hole diameter of the through-holes of the diaphragm is more than 0.1 μm and less than 50 μm.

2. The artificial photosynthesis module according to claim 1,
wherein the diaphragm is formed of a porous membrane having a hydrophilic surface.

3. The artificial photosynthesis module according to claim 1,
wherein the first electrode has a first substrate, a first conductive layer provided on the first substrate, a first photocatalyst layer provided on the first conductive layer, and a first co-catalyst carried and supported on at least a portion of the first photocatalyst layer,
wherein the second electrode has a second substrate, a second conductive layer provided on the second substrate, a second photocatalyst layer provided on the second conductive layer, and a second co-catalyst carried and supported on at least a portion of the second photocatalyst layer, and
wherein the first electrode, the diaphragm, and the second electrode are disposed in series in a traveling direction of the light.

4. The artificial photosynthesis module according to claim 2,
wherein the first electrode has a first substrate, a first conductive layer provided on the first substrate, a first photocatalyst layer provided on the first conductive layer, and a first co-catalyst carried and supported on at least a portion of the first photocatalyst layer,
wherein the second electrode has a second substrate, a second conductive layer provided on the second substrate, a second photocatalyst layer provided on the second conductive layer, and a second co-catalyst carried and supported on at least a portion of the second photocatalyst layer, and
wherein the first electrode, the diaphragm, and the second electrode are disposed in series in a traveling direction of the light.

5. The artificial photosynthesis module according to claim 3,
wherein the light is incident from the first electrode side, and the first substrate of the first electrode is transparent.

6. The artificial photosynthesis module according to claim 1,
wherein the first electrode and the second electrode have a plurality of through-holes, and
wherein the diaphragm is disposed and sandwiched between the first electrode and the second electrode.

7. The artificial photosynthesis module according to claim 2,
wherein the first electrode and the second electrode have a plurality of through-holes, and
wherein the diaphragm is disposed and sandwiched between the first electrode and the second electrode.

8. The artificial photosynthesis module according to claim 3,
wherein the first electrode and the second electrode have a plurality of through-holes, and
wherein the diaphragm is disposed and sandwiched between the first electrode and the second electrode.

9. The artificial photosynthesis module according to claim 1,
wherein the first fluid is a gas or a liquid, and the second fluid is a gas or a liquid.

10. The artificial photosynthesis module according to claim 2,
wherein the first fluid is a gas or a liquid, and the second fluid is a gas or a liquid.

11. The artificial photosynthesis module according to claim 3,
wherein the first fluid is a gas or a liquid, and the second fluid is a gas or a liquid.

12. The artificial photosynthesis module according to claim 1,
wherein the raw material fluid is water, the first fluid is oxygen, and the second fluid is hydrogen.

13. The artificial photosynthesis module according to claim 2,
wherein the raw material fluid is water, the first fluid is oxygen, and the second fluid is hydrogen.

14. The artificial photosynthesis module according to claim 3,
wherein the raw material fluid is water, the first fluid is oxygen, and the second fluid is hydrogen.

15. An artificial photosynthesis device comprising:
an artificial photosynthesis module that decomposes a raw material fluid to obtain a fluid;
a tank that stores the raw material fluid;
a supply pipe that is connected to the tank and the artificial photosynthesis module and supplies the raw material fluid to the artificial photosynthesis module;
a discharge pipe that is connected to the tank and the artificial photosynthesis module and recovers the raw material fluid from the artificial photosynthesis module;
a pump that circulates the raw material fluid between the tank and the artificial photosynthesis module via the supply pipe and the discharge pipe;
a gas recovery unit that recovers the fluids obtained by the artificial photosynthesis module,
wherein a plurality of the artificial photosynthesis modules are disposed, each artificial photosynthesis module including
a first electrode having a first substrate that decomposes the raw material fluid with light to obtain a first fluid, a first conductive layer provided on the first substrate, a first photocatalyst layer provided on the first conductive layer, and a first co-catalyst carried and supported on at least a portion of the first photocatalyst layer;
a second electrode having a second substrate that decomposes the raw material fluid with the light to obtain a second fluid, a second conductive layer provided on the second substrate, a second photocatalyst layer provided on the second conductive layer, and a second co-catalyst carried and supported on at least a portion of the second photocatalyst layer; and
a diaphragm provided between the first electrode and the second electrode,
wherein the first electrode and the second electrode are electrically connected to each other via a conducting wire,
wherein the diaphragm is formed of a membrane having through-holes, is immersed in pure water having a temperature of 25° C. for one minute, and has a light transmittance of 60% or more in a wavelength range of 380 nm to 780 nm in a state where the membrane is immersed in the pure water, and
wherein an average hole diameter of the through-holes of the diaphragm is more than 0.1 μm and less than 50 μm.

16. The artificial photosynthesis device according to claim 15,
wherein the artificial photosynthesis module has a first compartment provided with the first electrode, and a second compartment provided with the second electrode, which are partition by the diaphragm,
wherein the supply pipe supplies the raw material fluid to the first compartment and the second compartment,
wherein the discharge pipe recovers the raw material fluids of the first compartment and the second compartment,
wherein the raw material fluid of the first compartment and the raw material fluid of the second compartment in the artificial photosynthesis module are mixed with each other and stored in the tank that stores the raw material fluid, and
wherein the raw material fluids that are mixed with each other and stored in the tank are supplied to the first compartment and the second compartment via the supply pipe by the pump.

17. The artificial photosynthesis device according to claim 15,
wherein the first fluid is a gas or a liquid, and the second fluid is a gas or a liquid.

18. The artificial photosynthesis device according to claim 16,
wherein the first fluid is a gas or a liquid, and the second fluid is a gas or a liquid.

19. The artificial photosynthesis device according to claim 15,
wherein the raw material fluid is water, the first fluid is oxygen, and the second fluid is hydrogen.

20. The artificial photosynthesis device according to claim 16,
wherein the raw material fluid is water, the first fluid is oxygen, and the second fluid is hydrogen.
